(19) United States
(12) Patent Application Publication
(10) Pub. No.: US 2025/0383481 A1
(43) Pub. Date: Dec. 18, 2025

(54) LIGHT ABSORBER, LIGHT-ABSORBING COMPOUND, LIGHT-ABSORBING COMPOUND DISPERSION, LIGHT-ABSORBING COMPOSITION, OPTICAL FILTER, PHOTOELECTRIC CONVERSION ELEMENT, AMBIENT LIGHT SENSOR, AND IMAGING APPARATUS

(71) Applicant: Nippon Sheet Glass Company, Limited, Tokyo (JP)

(72) Inventor: Yuichiro KUBO, Tokyo (JP)

(21) Appl. No.: 18/878,723

(22) PCT Filed: May 30, 2023
(86) PCT No.: PCT/JP2023/020187

§ 371 Date: Dec. 24, 2024

(30) Foreign Application Priority Data
Jun. 24, 2022 (JP) 2022-102208

(51) Int. Cl. G02B 5/00; G02B 1/04; H10F 77/30; H10F 77/42

(52) U.S. Cl. CPC G02B 5/003; G02B 1/04; H10F 77/334; H10F 77/484

(57) ABSTRACT

A light absorber 10 has a transmission spectrum satisfying the following requirements (I), (II), (III), (IV), and (V) at an incident angle of 0°. The light absorber 10 has a haze less than 0.20%. (I) An average transmittance T^{A}_{0deg(460-600)} is 75% or more. (II) A shorter cut-off wavelength λ^{H}_{0deg(s)} is in a range of 390 nm to 450 nm. (III) A longer cut-off wavelength λ^{H}_{0deg(L)} is in a range of 600 nm to 680 nm. (IV) An average T^{A}_{0deg(300-380)} is 1.2% or less. (V) An average T^{A}_{0deg(750-1000)} is 1.2% or less.

### TECHNICAL FIELD

The present invention relates to a light absorber, a light-absorbing compound, a light-absorbing compound dispersion, a light-absorbing composition, an optical filter, a photoelectric conversion element, an ambient light sensor, and an imaging apparatus.

### BACKGROUND ART

In imaging apparatuses and ambient light sensors including a solid-state image sensing device such as a charge coupled device (CCD) or a complementary metal oxide semiconductor (CMOS), any of various optical filters is disposed ahead of the solid-state image sensing device. For example, imaging apparatuses can include optical filters in order to obtain images with good color reproduction. Ambient light sensors can include optical filters in order to adjust sensing of ambient light.

Solid-state image sensing devices generally have sensitivity over a wide wavelength range extending from ultraviolet to infrared regions. On the other hand, the visual sensitivity of humans lies only in a wavelength range from about 380 nm to about 780 nm, which is a so-called visible light region. Hence, a technique is known in which an optical filter for blocking a portion of infrared and ultraviolet light is disposed ahead of a solid-state image sensing device in an imaging apparatus in order to allow the spectral sensitivity of the solid-state image sensing device to approximate to the visual sensitivity of humans.

In particular, light-absorbing-type optical filters including a film or layer including a light absorbent have been attracting attention. The transmittance properties of an optical filter including a film including a light absorbent are unlikely to be dependent on the incident angle, and that makes it possible, for example, to obtain a favorable image with a smaller difference in color tone, less uneven in-plane coloring, and high color reproducibility even when light is obliquely incident on the optical filter in an imaging apparatus. Moreover, favorable images are easily obtained using light-absorbing-type optical filters because such optical filters do not include a light-reflecting film and thus can reduce occurrence of ghosting and flare caused by multiple reflection of light. Furthermore, optical filters including a film including a light absorbent are advantageous also in terms of size reduction and thickness reduction of imaging apparatuses.

For example, Patent Literature 1 describes an optical filter including an UV-IR absorbing layer. This UV-IR absorbing layer includes an UV-IR absorbent formed by a phosphonic acid and copper ions and capable of absorbing ultraviolet and infrared light. Furthermore, according to Patent Literature 1, the UV-IR absorbing layer has a haze of 5% or less. The UV-IR absorbing layer has a haze of 5% or less. For example, it is possible to obtain high-quality images with an imaging apparatus in which an optical filter including such an UV-IR absorbing layer is embedded.

### CITATION LIST

### Patent Literature

Patent Literature 1: JP 6606626 B1

### SUMMARY OF INVENTION

### Technical Problem

The technique described in Patent Literature 1 leaves room for further study in terms of enhancement of performance of optical filters. The present invention therefore provides a light absorber advantageous in terms of enhancement of performance of optical filters.

### Solution to Problem

The present invention provides a light absorber having a transmission spectrum satisfying the following requirements (I), (II), (III), (IV), and (V) at an incident angle of 0°:
(I) an average transmittance in a wavelength range of 460 nm to 600 nm is 75% or more;
(II) a shorter cut-off wavelength that lies in a wavelength range of 350 nm to 450 nm and at which a transmittance is 50% is in a range of 390 nm to 450 nm;
(III) a longer cut-off wavelength that lies in a wavelength range of 600 nm to 700 nm and at which a transmittance is 50% is in a range of 600 nm to 680 nm;
(IV) an average transmittance in a wavelength range of 300 nm to 380 nm is 1.2% or less; and
(V) an average transmittance in a wavelength range of 750 nm to 1100 nm is 1.2% or less, wherein
the light absorber has a haze less than 0.20%.

The present invention also provides a light-absorbing compound including:
a first light-absorbing compound including a copper component and a first phosphonic acid represented by the following formula (a), where R₁ is an alkyl group or a halogenated alkyl group in which at least one hydrogen atom in an alkyl group is substituted with a halogen atom; and
a second light-absorbing compound including a copper component and a second phosphonic acid represented by the following formula (b), where R₂ is an aryl group or a modified aryl group in which at least one hydrogen atom in an aryl group is substituted with a halogen atom, a nitro group, or a hydroxy group, wherein
a transmission spectrum of a dispersion of the light-absorbing compound satisfies the following requirements (i), (ii), (iii), and (iv):
(i) an average transmittance in a wavelength range of 460 nm to 600 nm is 85% or more;
(ii) a shorter cut-off wavelength that lies in a wavelength range of 350 nm to 450 nm and at which a transmittance is 50% is in a range of 380 nm to 420 nm;
(iii) a longer cut-off wavelength that lies in a wavelength range of 600 nm to 700 nm and at which a transmittance is 50% is in a range of 600 nm to 650 nm; and
(iv) an average transmittance in a wavelength range of 725 nm to 1000 nm is 5% to 20%.

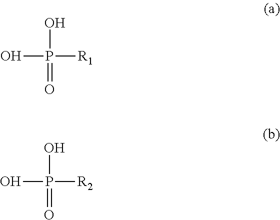

The present invention also provides a light-absorbing compound dispersion including:
a light-absorbing compound;
a solvent; and
an alkoxysilane or a hydrolysate of an alkoxysilane, wherein
the light-absorbing compound includes:
   a first light-absorbing compound including a copper component and a first phosphonic acid represented by the following formula (a), where R₁ is an alkyl group or a halogenated alkyl group in which at least one hydrogen atom in an alkyl group is substituted with a halogen atom; and
a second light-absorbing compound including a copper component and a second phosphonic acid represented by the following formula (b), where R₂ is an aryl group or a modified aryl group in which at least one hydrogen atom in an aryl group is substituted with a halogen atom, a nitro group, or a hydroxy group.

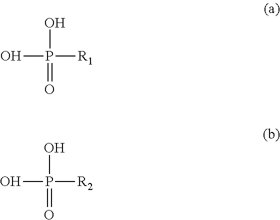

The present invention also provides a light-absorbing composition including:
a first light-absorbing compound including a copper component and a first phosphonic acid represented by the following formula (a), where R₁ is an alkyl group or a halogenated alkyl group in which at least one hydrogen atom in an alkyl group is substituted with a halogen atom;
a second light-absorbing compound including a copper component and a second phosphonic acid represented by the following formula (b), where R₂ is an aryl group or a modified aryl group in which at least one hydrogen atom in an aryl group is substituted with a halogen atom, a nitro group, or a hydroxy group;
a solvent; and
a binder, wherein
a ratio of an amount of the second phosphonic acid to an amount of the first phosphonic acid is 1.8 to 9 on a molar basis.

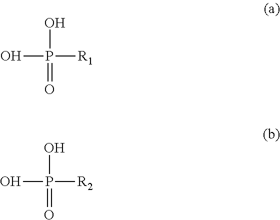

The present invention also provides an optical filter including the above light absorber.

The present invention also provides a photoelectric conversion element including:
a light-receiving face; and
the above light absorber, wherein
the light-receiving face and the light absorber are disposed in this order.

The present invention also provides an ambient light sensor including the above optical filter.

The present invention also provides an imaging apparatus including the above optical filter.

### Advantageous Effects of Invention

The above light absorber is advantageous in terms of enhancement of performance of optical filters.

### BRIEF DESCRIPTION OF DRAWINGS

FIG. 1A is a cross-sectional view showing an example of an optical filter according to the present invention.

FIG. 1B is a cross-sectional view showing another example of the optical filter according to the present invention.

FIG. 1C is a cross-sectional view showing yet another example of the optical filter according to the present invention.

FIG. 1D is a cross-sectional view showing yet another example of the optical filter according to the present invention.

FIG. 1E is a cross-sectional view showing yet another example of the optical filter according to the present invention.

FIG. 1F is a cross-sectional view showing yet another example of the optical filter according to the present invention.

FIG. 2A is a cross-sectional view showing an example of an ambient light sensor according to the present invention.

FIG. 2B is a cross-sectional view showing an example of a photoelectric conversion element according to the present invention.

FIG. 3A shows an example of an imaging apparatus according to the present invention.

FIG. 3B shows another example of the imaging apparatus according to the present invention.

FIG. 4 is a graph showing an example of a transmission spectrum of a substrate shown in FIG. 1B.

FIG. 5A is a graph showing transmission spectra of a light absorber according to Example 1 at different incident angles.

FIG. 5B is a graph showing reflection spectra of the light absorber according to Example 1 at different incident angles.

FIG. 5C is a graph showing a transmission spectrum of a light-absorbing compound dispersion according to Example 1.

FIG. 6 is a graph showing transmission spectra of a light absorber according to Example 2 at different incident angles.

FIG. 7 is a graph showing transmission spectra of a light absorber according to Example 3 at different incident angles.

FIG. 8A is a graph showing transmission spectra of a light absorber according to Example 4 at different incident angles.

FIG. 8B is a graph showing a transmission spectrum of a light-absorbing compound dispersion according to Example 4.

FIG. 9A is a graph showing transmission spectra of a light absorber according to Example 5 at different incident angles.

FIG. 9B is a graph showing reflection spectra of the light absorber according to Example 5 at different incident angles.

FIG. 9C is a graph showing a transmission spectrum of a light-absorbing compound dispersion according to Example 5.

FIG. 10 is a graph showing transmission spectra of a light absorber according to Example 6 at different incident angles.

FIG. 11 is a graph showing transmission spectra of a light absorber according to Example 7 at different incident angles.

FIG. 12A is a graph showing transmission spectra of a light absorber according to Example 8 at different incident angles.

FIG. 12B is a graph showing reflection spectra of the light absorber according to Example 8 at different incident angles.

FIG. 12C is a graph showing a transmission spectrum of a light-absorbing compound dispersion according to Example 8.

FIG. 13 is a graph showing a reflection spectrum of a light absorber according to Example 9 at an incident angle.

FIG. 14A is a graph showing a transmission spectrum of a light absorber according to Example 10 at an incident angle of 0°.

FIG. 14B is a graph showing a transmission spectrum of a light-absorbing compound dispersion according to Example 10.

FIG. 15 is a graph showing a transmission spectrum of a light absorber according to Example 11 at an incident angle of 0°.

FIG. 16 is a graph showing a transmission spectrum of a light absorber according to Example 12 at an incident angle of 0°.

FIG. 17A is a graph showing transmission spectra of an optical filter according to Example 13 at different incident angles.

FIG. 17B is a graph showing reflection spectra of the optical filter according to Example 13 at different incident angles.

FIG. 18 is a graph showing a transmission spectrum of a light absorber according to Comparative Example 1 at an incident angle of 0°.

FIG. 19 is a graph showing a transmission spectrum of a light absorber according to Comparative Example 2 at an incident angle of 0°.

FIG. 20A is a graph showing a transmission spectrum of a light absorber according to Reference Example 1 at an incident angle of 0°.

FIG. 20B is a graph showing the transmission spectrum of the light absorber according to Reference Example 1 at an incident angle of 0° and a change rate of transmittance with respect to wavelength.

FIG. 21A is a graph showing a transmission spectrum of the light absorber according to Reference Example 1 at an incident angle of 0°.

FIG. 21B is a graph showing the transmission spectrum of the light absorber according to Reference Example 1 at an incident angle of 0° and a change rate of transmittance with respect to wavelength.

### DESCRIPTION OF EMBODIMENTS

Due to worldwide prevalence of information terminals, such as smartphones, equipped with camera modules, quality of images obtained by cameras or performance of cameras are increasing day by day. Hence, enhancement of performance is strongly demanded also of optical filters to be embedded in imaging apparatuses or camera modules. In particular, specifications of a transmission spectrum of an optical filter that blocks ultraviolet light and infrared light are becoming stricter and more specific, and minimization of the haze of such an optical filter is also strongly demanded.

Patent Literature 1 describes an amount of copper ions in a composition for formation of an UV-IR absorbing layer, and also describes a preferred range of the viscosity of a liquid composition being a precursor of the UV-IR absorbing layer. However, a haze value of the UV-IR absorbing layer described in Patent Literature 1 is at least 0.2%. For example, performances of optical filters can further be enhanced if a light absorber capable of blocking ultraviolet light and infrared light and achieving a lower haze is provided. As a result of intensive studies, the present inventors finally found a light absorber that can achieve both a lower haze and given transmission properties that can allow the light absorber to block ultraviolet light and infrared light.

Embodiments of the present invention will be described hereinafter. The following description relates to examples of the present invention, and the present invention is not limited to the embodiments given below.

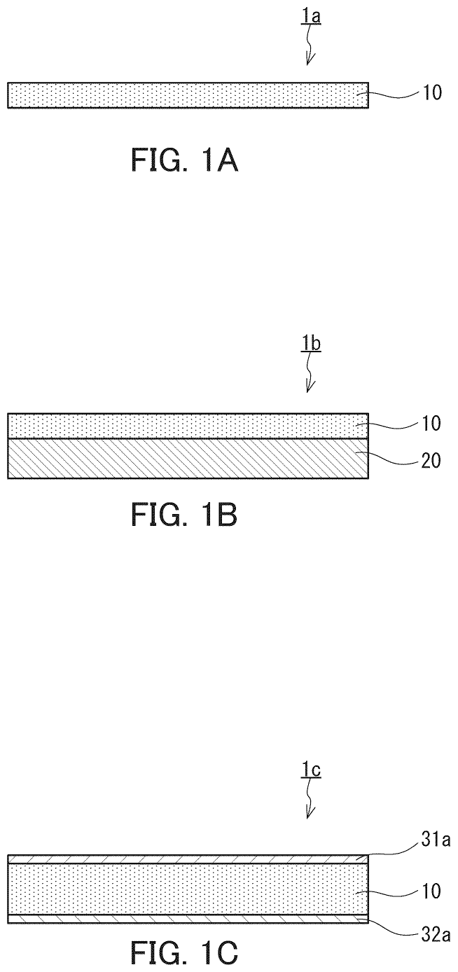

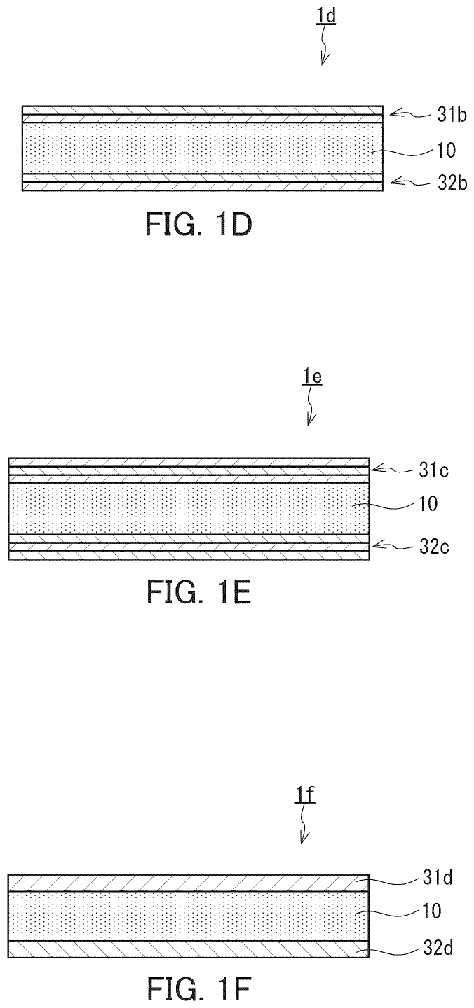

FIG. 1A is a cross-sectional view showing an optical filter 1a. As shown in FIG. 1A, the optical filter 1a includes a light absorber 10. The light absorber 10 has a transmission spectrum satisfying the following requirements (I), (II), (III), (IV), and (V) at an incident angle of 0°. Moreover, the light absorber 10 has a haze less than 0.20%.
(I) An average transmittance T^{A}_{0deg(460-600)} in a wavelength range of 460 nm to 600 nm is 75% or more.
(II) A shorter cut-off wavelength λ^{H}_{0deg(s)} that lies in a wavelength range of 350 nm to 450 nm and at which a transmittance is 50% is in a range of 390 nm to 450 nm.
(III) A longer cut-off wavelength λ^{H}_{0deg(L)} that lies in a wavelength range of 600 nm to 700 nm and at which a transmittance is 50% is in a range of 600 nm to 680 nm.
(IV) An average transmittance T^{A}_{0deg(300-380)} in a wavelength range of 300 nm to 380 nm is 1.2% or less.
(V) An average transmittance T^{A}_{0deg(750-1000)} in a wavelength range of 750 nm to 1100 nm is 1.2% or less.

Since the light absorber 10 satisfies the requirements (I), (II), and (III), the transmittance in a visible light region is likely to be high. In particular, since the light absorber 10 satisfies the requirement (III), the transmittance of the light absorber in a red band is likely to be high. Moreover, since satisfying the requirement (V), the light absorber 10 can block infrared light well.

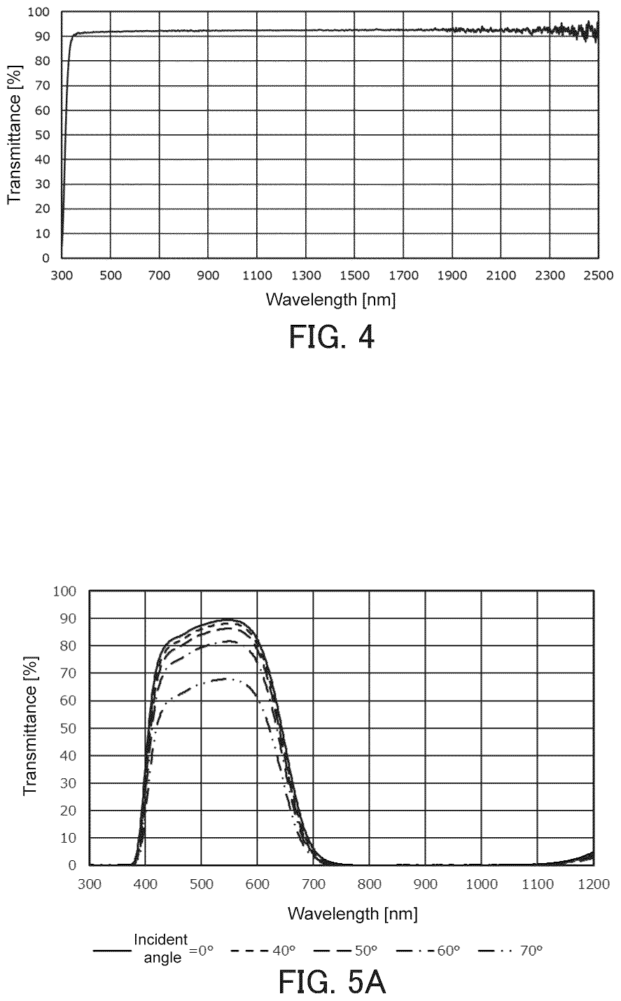

As shown in FIG. 1A, the light absorber 10 can be distributed by itself as the optical filter 1a. The light absorber 10 may be in the form of a film that absorbs a portion of light. The light absorber 10 may be in the form of a layer included in a functional film having multiple functions. The optical filter 1a may be configured as an optical filter 1b shown in FIG. 1B. The optical filter 1b includes a substrate 20 in addition to the light absorber 10. The light absorber 10 can be formed, for example, to cover at least a portion of a face of the substrate 20. The substrate 20 includes, for example, a resin, a glass, or a metal. One example of the substrate 20 is D263 T eco by Corning Incorporated. D263 T eco having a thickness of 3 mm has a transmission spectrum shown in FIG. 4 at an incident angle of 0°. In the transmission spectrum shown in FIG. 4, the transmittance in a wavelength range of 360 nm to 2300 nm is 90% or more, and the transmittance in a range of 335 nm to 2500 nm is 85% or more.

A transmission spectrum is determined, for example, by allowing light with wavelengths of 300 nm to 1200 nm to incident on a given target at a given incident angle (IA) and measuring light having passed through the target with a spectrophotometer or the like. A reflection spectrum is determined by allowing light with wavelengths of 300 nm to 1200 nm to incident on a given target at a given incident angle and measuring reflected light with a spectrophotometer or the like.

The light absorber 10 by itself may satisfy the requirements relating to the transmission spectrum, or an optical filter including a substrate and the light absorber 10 may satisfy the requirements relating to the transmission spectrum. In other words, an optical filter including a substrate and the light absorber 10 may satisfy the above requirements (I), (II), (III), (IV), and (V) at an incident angle of 0°, or may satisfy transmission spectrum requirements described below for the light absorber 10.

Herein, unless otherwise specified, the terms “visible region” and “visible light region” are defined as a wavelength range of 380 nm to 780 nm, and the term “red band” is defined as a band of a wavelength range extending from 580 nm to 780 nm or a band in a part of the wavelength range. Additionally, unless otherwise specified, infrared light is defined as light (electromagnetic wave) belonging to a wavelength range of more than 780 nm, which is the upper limit of the visible region, to 1400 nm, and this light corresponds to near-infrared light (NIR). Ultraviolet light is defined as light (electromagnetic wave) belonging to a wavelength range of 280 nm to less than 380 nm, which is the lower limit of the visible region, and this light corresponds to a portion of UV-A and UV-B.

Optical filters to be embedded in ambient light sensors, imaging apparatuses, and the like are naturally required to have appropriate transmission and reflection spectra. Meanwhile, for example, even if the transmittance in the visible region is high, a portion of light incident on an optical filter or a light absorber with a high haze can scatter or be diffused therein, and that can result in cloudiness and opaqueness. That can adversely affect formation of a sharp image. Contrarily, the light absorber 10, which satisfies the above requirements (I), (II), (III), (IV), and (V) and has a haze less than 0.20%, is likely to have a desired transmission spectrum and increase the transparency of optical filters. Therefore, the light absorber 10 is suitable in terms of enhancement of the quality of an image obtained by an imaging apparatus. Additionally, the light absorber 10 easily increases the accuracy of sensing of ambient light in an ambient light sensor.

The value of the haze of the light absorber 10 may be determined by measuring the light absorber 10 alone or an optical filter including the light absorber 10 provided on a substrate made of glass, resin, or the like.

The haze of the light absorber 10 may be 0.19% or less, and is desirably 0.18% or less, and more desirably 0.15% or less.

As for the above requirement (I), the average transmittance T^{A}_{0deg(460-600)} is desirably 80% or more, and more desirably 85% or more. Furthermore, in the transmission spectrum of the light absorber 10 at an incident angle of 0° in a wavelength range of 300 nm to 1100 nm, a maximum transmittance may be seen in a wavelength range of 500 nm to 600 nm. In this case, since a region of the highest visual sensitivity is in the range of 500 nm to 600 nm in a visual sensitivity spectrum (visual sensitivity curve) of humans, an image that gives a brighter impression can be obtained.

As for the above requirement (II), the shorter cut-off wavelength λ^{H}_{0deg(s)} is desirably in a range of 400 nm to 450 nm, may be in a range of 400 nm to 440 nm, 400 nm to 430 nm, or 400 nm to 420 nm.

As for the above requirement (III), the longer cut-off wavelength λ^{H}_{0deg(L)} is desirably in a range of 610 nm to 680 nm, and more desirably in a range of 620 to 680 nm. The longer cut-off wavelength λ^{H}_{0deg(L)} may be in a range of 620 nm to 670 nm, or 620 nm to 660 nm.

As for the above requirement (IV), the average transmittance T^{A}_{0deg(300-380)} is desirably 1% or less, and more desirably 0.5% or less.

As for the above requirement (V), the average transmittance T^{A}_{0deg(750-1000)} is desirably 1% or less, and more desirably 0.5% or less.

The light absorber 10 may have, for example, a reflection spectrum satisfying the following requirements (VI) and (VII) at an incident angle of 5°.
(VI) A maximum reflectance R^{M}_{5deg(300-400)} in a wavelength range of 300 nm to 400 nm is 7.5% or less.
(VII) A maximum reflectance R^{M}_{5deg(700-1200)} in a wavelength range of 700 nm to 1200 nm is 7.5% or less.

When an optical filter including the light absorber 10 satisfying the above requirements (VI) and (VII) is embedded in an imaging apparatus and a portion of light is reflected by the optical filter, reflection of the portion of light at a surface of a housing, a frame, or an optical system such as a diaphragm and a lens, of the imaging apparatus or projection of a shadow of the diaphragm or the shape of the diaphragm by the portion of light can be reduced, and accordingly incidence of a portion of such light on the imaging device can be reduced. Therefore, incidence of disadvantageous light, such as ghosting and flare, on the imaging device can be reduced, the disadvantageous light not contributing to image formation. Additionally, the above properties allow an optical filter for blocking a portion of light to fulfill its purpose by the action and function of the light absorber 10 alone and without a light-reflecting film formed of a dielectric multilayer film or the like.

As for the above requirement (VI), the maximum reflectance R^{M}_{5deg(300-400)} is desirably 7.0% or less, more desirably 6.5% or less, and even more desirably 6% or less.

As for the above requirement (VII), the maximum reflectance R^{M}_{5deg(700-1200)} is desirably 7.0% or less, more desirably 6.5% or less, and even more desirably 6% or less.

The light absorber 10 may have, for example, a transmission spectrum satisfying the following requirements (1-i), (1-ii), (1-iii), and (1-iv) at incident angles of 0°, 40°, 50°, 60°, and 70°. In the following requirements, λ^{H}_{40deg(S)}, λ^{H}_{50deg(S)}, λ^{H}_{60deg(S)}, and λ^{H}_{70deg(S)} are, in transmittance spectra respectively at incident angles of 40°, 50°, 60°, and 70°, shorter cut-off wavelengths that lie in the wavelength range of 350 nm to 450 nm and at which the transmittance is 50%.

$${λ}_{40 deg ( S )}^{H} - {λ}_{0 deg ( S )}^{H} \leq 2.5 nm \qquad ( 1 - i )$$

$${λ}_{50 deg ( S )}^{H} - {λ}_{0 deg ( S )}^{H} \leq 4.5 nm \qquad ( 1 - ii )$$

$${λ}_{60 deg ( S )}^{H} - {λ}_{0 deg ( S )}^{H} \leq 7.5 nm \qquad ( 1 - iii )$$

$${λ}_{70 deg ( S )}^{H} - {λ}_{0 deg ( S )}^{H} \leq 20 nm \qquad ( 1 - iv )$$

The light absorber 10 may have, for example, a transmission spectrum satisfying the following requirements (2-i), (2-ii), (2-iii), and (2-iv) at incident angles of 0°, 40°, 50°, 60°, and 70°. In the following requirements, λ^{H}_{40deg(L)}, λ^{H}_{50deg(L)}, λ^{H}_{60deg(L)}, and λ^{H}_{70deg(L)} are, in transmittance spectra respectively at incident angles of 40°, 50°, 60°, and 70°, longer cut-off wavelengths that lie in the wavelength range of 600 nm to 700 nm and at which the transmittance is 50%.

$${λ}_{0 deg ( L )}^{H} - {λ}_{40 deg ( L )}^{H} \leq 4 nm \qquad ( 2 - i )$$

$${λ}_{0 deg ( L )}^{H} - {λ}_{50 deg ( L )}^{H} \leq 7 nm \qquad ( 2 - ii )$$

$${λ}_{0 deg ( L )}^{H} - {λ}_{60 deg ( L )}^{H} \leq 12 nm \qquad ( 2 - iii )$$

$${λ}_{0 deg ( L )}^{H} - {λ}_{70 deg ( L )}^{H} \leq 30 nm \qquad ( 2 - iv )$$

When an optical filter including the light absorber 10 satisfying the requirements (1-i) to (1-iv) and (2-i) to (2-iv) is embedded in an imaging apparatus, a difference in color tone is less likely to be created between a region in which light incident on the optical filter at a small incident angle contributes to image formation and a region in which light incident on the optical filter at a relatively large incident angle contributes to image formation. Specifically, a difference in color tone is less likely to be created between a central portion and a peripheral portion of an image obtained with the imaging apparatus, and, even in the case where the imaging apparatus includes a wide-angle lens or an ultrawide-angle lens, a difference in color tone or the like is less likely to be created in an image obtained with the imaging apparatus.

The light absorber 10 typically includes a given light absorbent. The light absorbent included in the light absorber is not limited to a particular substance as long as the transmission spectrum of the light absorber 10 at an incident angle of 0° satisfies the above requirements (I) to (V) and the light absorber 10 has a haze less than 0.20%.

The light absorber 10 can be manufactured, for example, by curing a liquid light-absorbing composition. The light absorber 10 may be a film, or may be a film formed on a given object made of glass, resin, or the like. The light absorber 10 can be solid.

The light-absorbing composition includes a light-absorbing compound and a binder. A light-absorbing compound dispersion may be used to prepare the light-absorbing composition. A compound that contributes to achievement of the given transmission spectrum, reflection spectrum, or small haze value of the light absorber 10 or a precursor of such a compound is naturally included in the light-absorbing composition being a precursor of the light absorber 10 and the dispersion in which the light-absorbing compound included in the light-absorbing composition is dispersed. The light-absorbing compound dispersion may be hereinafter referred to as “light-absorbing dispersion”. The light-absorbing dispersion includes the light-absorbing compound as does the light-absorbing composition, but is different from the light-absorbing composition in that the light-absorbing dispersion is free of a compound that is cured by heating or application of an electromagnetic wave such as light. To cure a resin means to cause a reaction for polymerization of a portion of a functional group in the resin by heating, leaving the resin alone, or application of an electromagnetic wave such as light to form a polymer structure and cure the resin irreversibly.

The light-absorbing composition includes, for example, the light-absorbing compound, a solvent, and the binder. The light-absorbing composition may further include a dispersant, if necessary. The dispersant contributes to dispersion of the light-absorbing compound in the solvent. As a precursor of the light absorber, the light-absorbing composition may be curable by heating or application of an electromagnetic wave. Moreover, the light-absorbing composition is not limited to a particular composition as long as a light absorber formed by curing the light-absorbing composition satisfies the above requirements (I) to (V). This light absorber desirably has a haze less than 0.20%.

The light-absorbing compound can be, for example, a compound including a phosphonic acid and a copper component, a compound including a phosphoric acid ester and a copper component, a compound including a phosphoric acid and a copper component, a phosphoric acid-copper complex represented by MₙCu_{y}PO_{4-z} (where M is a metal element other than Cu), a compound including a sulfonic acid and a copper component, a compound including a tungsten oxide, a metal oxide such as ITO or ATO, or a known organic-dye-based compound. Examples of the organic-dye-based compound include a diimmonium-based compound, a cyanine-based compound, a squarylium-based compound, a phthalocyanine-based compound, and a pyrrolopyrrole-based compound. For example, the light absorber 10 may include: the light-absorbing compound including a phosphonic acid and a copper component as the light absorbent; and an ultraviolet absorbent capable of absorbing at least a portion of ultraviolet light.

Among these, a compound including a phosphonic acid and a copper component, a compound including a phosphoric acid ester and a copper component, a compound including phosphoric acid and a copper component, a compound including a sulfonic acid and a copper component, and these compounds formed as complexes are advantageous as the light absorbent, the compounds each having a broad absorption band in an infrared region. This is because blocking of light in given wavelength ranges can be achieved only by means of the light absorption action of the light absorber 10. In the light absorber 10, one of these compounds may be used alone, or a mixture of two or more of these compounds may be used. A phosphonic acid, a phosphoric acid ester, and phosphoric acid are oxides including phosphorus (P), and may coexist. For example, a compound including a phosphonic acid, a phosphoric acid ester, a copper component may be present in the light absorber 10. Even in the case where a complex including a phosphonic acid and a copper component is obtained as the light absorbent, a phosphoric acid ester may be added as a dispersant. In this case, the light absorber 10 may include a compound including the phosphonic acid, the phosphoric acid ester, and the copper component.

The phosphonic acid included in the light-absorbing compound is not limited to a particular phosphonic acid as long as the transmission spectrum of the light absorber 10 at an incident angle of 0° satisfies the requirements (I) to (V) and the light absorber 10 has a haze less than 0.20%. The phosphonic acid includes, for example, a first phosphonic acid represented by the following formula (a). In the formula (a), R₁ is an alkyl group or a halogenated alkyl group in which at least one hydrogen atom in an alkyl group is substituted with a halogen atom. In this case, a transmission band of the light absorber 10 is likely to extend to a wavelength around 700 nm, and the light absorber 10 is likely to have the desired transmittance properties. Phosphonic acids having the above groups are collectively called alkylphosphonic acids. The phosphonic acid in the light-absorbing compound includes, for example, a second phosphonic acid represented by the following formula (b). In the formula (b), R₂ is an aryl group or a modified aryl group in which at least one hydrogen atom in an aryl group is substituted with a halogen atom, a nitro group, or a hydroxy group. This makes it more likely that the optical filter 1a has the desired transmittance properties. Phosphonic acids having the above groups are collectively called arylphosphonic acids. The modified aryl group is, for example, a halogenated phenyl group.

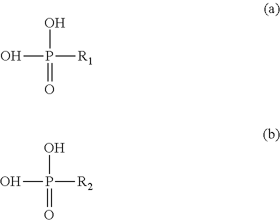

The first phosphonic acid is, for example, methylphosphonic acid, ethylphosphonic acid, normal(n-)propylphosphonic acid, isopropylphosphonic acid, normal(n-)butylphosphonic acid, isobutylphosphonic acid, sec-butylphosphonic acid, tert-butylphosphonic acid, or bromomethylphosphonic acid.

The second phosphonic acid is, for example, phenylphosphonic acid, bromophenylphosphonic acid, benzylphosphonic acid, fluorophenylphosphonic acid, iodophenylphosphonic acid, nitrophenylphosphonic acid, hydroxyphenylphosphonic acid, tolylphosphonic acid, xylylphosphonic acid, or naphthylphosphonic acid.

The light absorber 10, the light-absorbing composition, and the light-absorbing dispersion may include one phosphonic acid or two or more phosphonic acids selected from the above phosphonic acids.

The phosphonic acid included in the light absorber 10, the light-absorbing composition, and the light-absorbing dispersion may include the first phosphonic acid and the second phosphonic acid. In this case, the phosphonic acid may include one first phosphonic acid or two or more first phosphonic acids, and may include one second phosphonic acid or two or more second phosphonic acids. The light absorber 10, the light-absorbing composition, and the light-absorbing dispersion may include a first light-absorbing compound and a second light-absorbing compound. The first light-absorbing compound includes a copper component and the first phosphonic acid. The second light-absorbing compound includes a copper component and the second phosphonic acid.

In the light absorber 10, the light-absorbing composition, and the light-absorbing dispersion, a ratio α_{ar/ak} of an amount of the second phosphonic acid to an amount of the first phosphonic acid is not limited to a particular value. The ratio α_{ar/ak} is, for example, 1.8 to 9 on a molar basis. If a compound partially makes an aggregate and settles down in preparation of a light-absorbing composition or a light-absorbing dispersion, the haze of the resulting light absorber becomes so high that the light absorber is unsuitable for an imaging apparatus. On the other hand, since the ratio α_{ar/ak} is 9 or less, the compounds can be prevented from partially making an aggregate and settling down in preparation of the light-absorbing composition or the light-absorbing dispersion. Consequently, the light absorber 10 is likely to have a haze less than 0.20%. Additionally, since the ratio α_{ar/ak} is 1.8 or more, the shorter cut-off wavelength and the longer cut-off wavelength can be prevented from becoming, respectively, shorter and longer than the given ranges. As a result, the transmittance of the light absorber 10 in the visible region is likely to be high.

Since the ratio α_{ar/ak} is 1.8 or more, in a wavelength range of 420 nm to 480 nm in transmission spectra of the light absorber or the optical filter, appearance of at least one plateau in each transmission spectrum curve is likely to be prevented. Such a plateau can be salient when a difference between the maximum dT/dλₘₐₓ and the minimum dT/dλₘᵢₙ of a change rate dT/dλ [%/nm] of the transmittance with respect to the wavelength is 0.2 [%/nm] or more in the wavelength range of 420 nm to 480 nm or the minimum dT/dλₘᵢₙ of the change rate of the transmittance with respect to the wavelength is 0.2 [%/nm] or less in the wavelength range of 420 nm to 480 nm. The symbol T in dT/dλ is the transmittance [%], and λ in dT/dλ is the wavelength [nm]. Such a plateau can have an adverse effect on inclusion of the light absorber or the optical filter in an imaging apparatus or an ambient light sensor.

The ratio α_{ar/ak} is desirably 2 or more, more desirably 3 or more, even more desirably 4 or more, particularly desirably 5.5 or more, and especially desirably 6.0 or more. The ratio α_{ar/ak} is desirably 8.5 or less, more desirably 8.0 or less, and even more desirably 7.5 or less.

In the light absorber 10, the light-absorbing composition, and the light-absorbing dispersion, the concept of the copper component includes a compound including copper ions, a copper complex, and copper. The copper component can have preferred absorption properties in terms of a portion of light belonging to the near-infrared region and a high light transmittivity in a wavelength range from 450 nm to 680 nm within the visible region. Specifically, by electron transition in the d orbital of a divalent copper ion, light corresponding to this electron transition energy and having a wavelength belonging to the near-infrared region is selectively absorbed and thus excellent near-infrared absorption properties are exhibited. In particular, the copper component including divalent copper ions is supplied in the form of a copper salt and mixed with the phosphonic acid to form a copper complex (copper salt) by coordination of the phosphonic acid to the copper component including the copper ions.

A supply source of the copper component supplied for coordination of the phosphonic acid may be, but not limited to, a copper salt anhydride or copper salt hydrate, such as copper acetate, copper benzoate, copper pyrophosphate, or copper stearate, of an organic acid, or a mixture thereof. One of these copper salts may be used alone, or two or more of these copper salts or a mixture thereof may be used.

In the light absorber 10, the light-absorbing composition, and the light-absorbing dispersion, a ratio α_{PC} of an amount of the phosphonic acid to an amount of the copper component is not limited to a particular value. The ratio α_{PC} is, for example, 0.3 to 3 on a molar basis. When both the first phosphonic acid and the second phosphonic acid are included, the ratio α_{PC} can be a sum of the amount of the first phosphonic acid and the amount of the second phosphonic acid to the amounts of the copper components. When the ratio α_{PC} is in the range of 0.3 to 3, the light absorbent is likely to be formed with no excess nor shortage of elements and groups. Hence, oxidation is less likely to occur and a favorable weather resistance is likely to be exhibited in the light absorber 10, the light-absorbing composition, and the light-absorbing dispersion.

The ratio α_{PC} is desirably 0.4 to 2, and more desirably 0.6 to 1.2 on a molar basis.

In the light absorber 10, the light-absorbing composition, and the light-absorbing dispersion, the ratio α_{ak/c} and the ratio α_{ar/c} are not limited to particular values when both the first phosphonic acid and the second phosphonic acid are included. The ratio α_{ak/c} is a ratio of the amount of the first phosphonic acid to the amounts of the copper components, and the ratio α_{ar/c} is a ratio of the amount of the second phosphonic acid to the amounts of the copper components. The ratio α_{ak/c} is, for example, 0.05 to 0.8 on a molar basis. The ratio α_{ak/c} is desirably 0.1 to 0.4, and more desirably 0.1 to 0.3. The ratio α_{ar/c} is, for example, 0.2 to 1.5, desirably 0.4 to 1.2, and more desirably 0.5 to 1 on a molar basis.

The light absorber 10, the light-absorbing composition, and the light-absorbing dispersion may further include a phosphoric acid ester compound. The phosphoric acid ester facilitates appropriate dispersion of the light-absorbing compound (light absorbent) in the light absorber 10, the light-absorbing composition, and the light-absorbing dispersion. The phosphoric acid ester may function as a dispersant for the light-absorbing compound. A portion of the phosphoric acid ester may react with a metal component to form the light-absorbing compound. For example, the phosphoric acid ester may coordinate to the light-absorbing compound or may react with another portion of the light-absorbing compound, or a portion of the phosphoric acid ester may form a complex with the copper component. The compound including the phosphoric acid ester and the copper component may absorb light with a certain wavelength as long as the transmission spectrum of the light absorber 10 at an incident angle of 0° satisfies the requirements (I) to (V). The light absorber 10, the light-absorbing composition, and the light-absorbing dispersion may be substantially free of the phosphoric acid ester or may be completely free of the phosphoric acid ester as long as the light-absorbing compound including at least the phosphonic acid and the copper component is suitably dispersed in the light-absorbing composition being a precursor of the light absorber or the light-absorbing dispersion. For example, in the case where the light-absorbing composition includes an alkoxysilane monomer described below as a dispersant, the amount of the phosphoric acid ester added can be decreased.

The phosphoric acid ester is not limited to a particular phosphoric acid ester or a particular compound thereof. The phosphoric acid ester has, for example, a polyoxyalkyl group. Examples of the phosphoric acid ester include PLYSURF A208N (polyoxyethylene alkyl (C12, C13) ether phosphoric acid ester), PLYSURF A208F (polyoxyethylene alkyl (C8) ether phosphoric acid ester), PLYSURF A208B (polyoxyethylene lauryl ether phosphoric acid ester), PLYSURF A219B (polyoxyethylene lauryl ether phosphoric acid ester), PLYSURF AL (polyoxyethylene styrenated phenylether phosphoric acid ester), PLYSURF A212C (polyoxyethylene tridecyl ether phosphoric acid ester), and PLYSURF A215C (polyoxyethylene tridecyl ether phosphoric acid ester). All of these are products manufactured by DKS Co., Ltd. Examples of the phosphoric acid ester include NIKKOL DDP-2 (polyoxyethylene alkyl ether phosphoric acid ester), NIKKOL DDP-4 (polyoxyethylene alkyl ether phosphoric acid ester), and NIKKOL DDP-6 (polyoxyethylene alkyl ether phosphoric acid ester). All of these are products manufactured by Nikko Chemicals Co., Ltd. One of these phosphoric acid ester compounds may be used alone, or two or more of these phosphoric acid ester compounds may be used in combination.

In the light absorber 10, the light-absorbing composition, and the light-absorbing dispersion, a ratio β_{p/es} of the amount of the phosphonic acid to an amount of the phosphoric acid ester is not limited to a particular value. The ratio β_{p/es} is, for example, 1 to 3 on a mass basis. In this case, hydrolysis of the phosphoric acid ester is reduced even when the light absorber 10 comes into contact with water vapor or dampness, and thus the light absorber 10 is likely to have a favorable weather resistance. The ratio of the amount of the phosphonic acid to the amount of the phosphoric acid ester in the light absorber 10 is desirably 1.2 to 3.8, and more desirably 1.5 to 2.5.

The light absorber 10, the light-absorbing composition, and the light-absorbing dispersion may further include, for example, an alkoxysilane or a hydrolysate of an alkoxysilane. The term alkoxysilane includes an alkoxysilane monomer, a hydrolysate of a portion of an alkoxysilane monomer, and a dimer or polymer formed by polymerization of at least a portion of a hydrolysate of an alkoxysilane. The presence of the alkoxysilane can prevent aggregation of particles of the light absorbent; therefore, even when the amount of the phosphoric acid ester is decreased, the light absorbent is likely to be dispersed well in the light-absorbing composition or a light absorber formed by curing the light-absorbing composition. Moreover, for example, when a light absorber or an optical filter is manufactured using the light-absorbing composition, by performing a treatment so that a hydrolysis reaction and a polycondensation reaction of an alkoxysilane monomer will occur sufficiently, a siloxane bond (—Si—O—Si—) is formed and the light absorber has a high humidity resistance. Furthermore, the light absorber has a high thermal resistance. This is because a siloxane bond is chemically stable owing to its high binding energy and is excellent in thermal resistance and humidity resistance, compared to, for example, a —C—C— bond and a —C—O— bond.

When a light absorber is produced by curing the light-absorbing composition including the alkoxysilane, a so-called humidification treatment, i.e. exposure to an atmosphere having a relatively high humidity for a certain period of time, may be performed. It is thought that by the humidification treatment, a water component in the atmosphere promotes hydrolysis of the alkoxysilane in the light-absorbing composition or the light absorber to facilitate formation of a siloxane bond. Moreover, a hard and dense light absorber is likely to be formed by the humidification treatment without aggregation of fine particles including the light absorbent.

The alkoxysilane is not limited to a particular alkoxysilane as long as the alkoxysilane can form, in the resulting light absorber, a hydrolysis-polycondensation compound having a siloxane bond by a hydrolysis reaction and a polycondensation reaction. The alkoxysilane may be, for example, a monomer of tetramethoxysilane, tetraethoxysilane, methyltrimethoxysilane, methyltriethoxysilane, dimethyldiethoxysilane, dimethyldimethoxysilane, phenyltrimethoxysilane, phenyltriethoxysilane, 3-glycidoxypropyltrimethoxysilane, 3-glycidoxypropyltriethoxysilane, 3-glycidoxypropylmethyldiethoxysilane, or the like, or may be a dimer or oligomer formed by binding a portion thereof.

The binder included in the light absorber 10 and the light-absorbing composition may include a curable resin. The curable resin is not limited to a particular resin. The curable resin is, for example, capable of holding the above light-absorbing compound including the phosphonic acid and the copper component or another light-absorbing compound in a dispersed or dissolved state. Moreover, it is desirable that when not cured or reacted yet, the curable resin be liquid and be a resin in which at least the above light-absorbing compound including the phosphonic acid and the copper component can be dispersed or dissolved. Furthermore, it is desirable that when being an uncured liquid holding the light-absorbing compound therein, the curable resin can form a coating film by application of the curable resin to a given object by a method such as spin coating, spray coating, dip coating, or dispensing. The object on which the coating film is formed is a substrate having a given surface which may be flat or curved. The uncured liquid resin can be cured desirably by heating, humidification, application of energy such as light, or a combination of these. Either of the following requirements can be satisfied: the transmission spectrum of the light absorber 10 at an incident angle of 0° satisfies the requirements (I) to (V); and a 1 mm-thick plate-shaped body having a flat and smooth surface formed by curing the resin has a transmittance of 90% or more in a wavelength range of 450 nm to 800 nm. Examples of the curable resin include a cyclic polyolefin resin, an epoxy-based resin, a polyimide-based resin, a modified acrylic resin, a silicone resin, and a polyvinyl-based resin (PVA) such as polyvinyl butyral (PVB).

The light absorber 10 and the light-absorbing composition may include a curing catalyst being a catalyst that promotes curing of the curable resin. The curing catalyst can be a catalyst for controlling conditions such as the curing speed of the curable resin, the curing reactivity of the resin, and the hardness of the resin after curing.

The curing catalyst is desirably an organic compound including a metal component. The organic metal compound is not limited to a particular compound. An organic aluminum compound, an organic titanium compound, an organic zirconium compound, an organic zinc compound, an organic tin compound, or the like may be used as the organic metal compound.

The organic aluminum compound is not limited to a particular compound. Examples of the organic aluminum compound can include: aluminum salt compounds such as aluminum triacetate and aluminum octylate; aluminum alkoxide compounds such as aluminum trimethoxide, aluminum triethoxide, aluminum dimethoxide, aluminum diethoxide, aluminum triallyloxide, aluminum diallyloxide, and aluminum isopropoxide; and aluminum chelate compounds such as aluminum methoxy bis(ethyl acetoacetate), aluminum methoxy bis(acetylacetonate), aluminum ethoxy bis(ethyl acetoacetate), aluminum ethoxy bis(acetylacetonate), aluminum isopropoxy bis(ethyl acetoacetate), aluminum isopropoxy bis(methyl acetoacetate), aluminum isopropoxy bis(t-butyl acetoacetate), aluminum butoxy bis(ethyl acetoacetate), aluminum dimethoxy(ethyl acetoacetate), aluminum dimethoxy(acetylacetonate), aluminum diethoxy(ethyl acetoacetate), aluminum diethoxy(acetylacetonate), aluminum diisopropoxy(ethyl acetoacetate), aluminum diisopropoxy(methyl acetoacetate), aluminum tris(ethyl acetoacetate), and aluminum tris(acetylacetonate). One of these may be used alone, or two or more of these may be used in combination.

The organic titanium compound is not limited to a particular compound. Examples of the organic titanium compound can include: titanium chelates such as titanium tetraacetylacetonate, dibutyloxytitanium diacetylacetonate, titanium ethyl acetoacetate, titanium octylene glycollate, and titanium lactate; and titanium alkoxides such as tetraisopropyltitanate, tetrabutyltitanate, tetramethyltitanate, tetra(2-ethylhexyl titanate), titanium tetra-2-ethylhexoxide, a titanium butoxy dimer, titanium tetra-normal-butoxide, titanium tetraisopropoxide, and titanium diisopropoxy bis(ethyl acetoacetate). One of these may be used alone, or two or more of these may be used in combination.

The organic zirconium compound is not limited to a particular compound. Examples of the organic zirconium compound can include: zirconium chelates such as zirconium tetraacetylacetonate, zirconium dibutoxy bis(ethyl acetoacetate), zirconium monobutoxy acetylacetonate bis(ethyl acetoacetate), zirconium tributoxy monoacetylacetonate, and zirconium tetraacetylacetonate; and zirconium alkoxides such as zirconium tetra-normal-butoxide and zirconium tetra-normal-propoxide. One of these may be used alone, or two or more of these may be used in combination.

Examples of the organic zinc compound can include zinc alkoxides such as dimethoxy zinc, diethoxy zinc, and ethylmethoxy zinc. One of these may be used alone, or two or more of these may be used in combination.

Examples of the organic tin compounds can include tin alkoxides such as dimethyltin oxide, diethyltin oxide, dipropyltin oxide, dibutyltin oxide, dipentyltin oxide, dihexyltin oxide, diheptyltin oxide, and dioctyltin oxide

One of these may be used alone, or two or more of these may be used in combination.

The curing catalyst may further include at least one of an alkoxide including a metal component, as described above, and a hydrolysate of an alkoxide including a metal component. Alkoxides including metal components and hydrolysates of alkoxides including metal components are collectively called “metal alkoxide compounds”. The metal alkoxide is a compound that is represented by a general formula M(OR)ₙ (where M is a metal element, and n is an integer of one or greater) and in which a hydrogen atom in a hydroxy group of an alcohol is substituted with the metal element M. The metal alkoxide forms an M—OH bond by hydrolysis, and forms an M—O—M bond by a reaction with a metal alkoxide of another molecule. For example, in the case where the light-absorbing composition being fluid and including a compound such as the curable resin is cured to form the light absorber 10, the metal alkoxide compound may be one that can function as a catalyst that promotes curing of the light-absorbing composition. The higher a heating treatment temperature is at the time of curing the light-absorbing composition by a heating treatment, the higher the environmental durability such as the thermal resistance can be. However, a high heating treatment temperature can result in deterioration of the properties of some light-absorbing compounds or an ultraviolet absorbent described later. The deterioration of the properties of the ultraviolet absorbent can result in a shift of the wavelength of light absorbed by the ultraviolet absorbent from an intended absorption wavelength. Additionally, the absorption ability of the ultraviolet absorbent can decline or disappear. As for the light absorber including the metal alkoxide compound, it is possible to promote curing of the light-absorbing composition at a relatively low heating treatment temperature. Consequently, the light absorber 10 is likely to have high environmental durability.

The metal component included in the metal alkoxide compound is not limited to a particular component. Examples of the metal component include Al, Ti, Zr, Zn, Sn, and Fe. For example, CAT-AC or DX-9740 being an aluminum alkoxide manufactured by Shin-Etsu Chemical Co., Ltd., ORGATIXAL-3001 being an aluminum alkoxide manufactured by Matsumoto Fine Chemical Co., Ltd., aluminum isopropoxide being an aluminum alkoxide manufactured by Tokyo Chemical Industry Co., Ltd., D-20, D-25, or DX-175 being a titanium alkoxide manufactured by Shin-Etsu Chemical Co., Ltd., ORGATIX TA-8, TA-21, TA-30, TA-80, or TA-90 being a titanium alkoxide manufactured by Matsumoto Fine Chemical Co., Ltd., D-15 or D-31 being a zirconia alkoxide manufactured by Shin-Etsu Chemical Co., Ltd., or ORGATIX ZA-45 or ZA-65 being a zirconia alkoxide manufactured by Matsumoto Fine Chemical Co., Ltd. can be used as the metal alkoxide.

In the light absorber 10 and the light-absorbing composition, a ratio γ_{MC} of the amount of the copper component to an amount of the metal component included in the metal alkoxide compound is not limited to a particular value. The ratio γ_{MC} is, for example, 1×10² to 7×10², desirably 2×10² to 6×10², and more desirably 3×10² to 5×10² on a mass basis.

In the light absorber 10 and the light-absorbing composition, a ratio γ_{MP} of an amount of the phosphorus component to the amount of the metal component included in the metal alkoxide compound is not limited to a particular value. The ratio γ_{MP} is, for example, 0.5×10² to 5×10², desirably 1×10² to 4×10², and more desirably 1.5×10² to 3×10² on a mass basis.

The light absorber 10 and the light-absorbing composition may include an ultraviolet absorbent capable of absorbing a portion of light belonging to ultraviolet light. The ultraviolet absorbent is not limited to a particular compound as long as the transmission spectrum of the light absorber 10 at an incident angle of 0° satisfies the requirements (I) to (V). The ultraviolet absorbent is, for example, a compound not having both a hydroxy group and a carbonyl group per molecule, and is a compound not having both a hydroxy group and a carbonyl group in one molecule when expressed by a structural formula. Curing of the light-absorbing composition can be promoted, for example, by coordination of a reacting substance or a precursor to a particular position in a molecule such as the alkoxide including the metal component. For example, if there is a group more likely to be coordinated to a substance other than a substance supplied for a reaction for curing the light-absorbing composition, the action of the catalyst may be weakened. In particular, if the alkoxide compound is reacted with or coordinated to an ultraviolet absorbent having a hydroxy group and a carbonyl group, both of which are highly electron donative, to partially form a complex, inherent UV-absorption properties of the ultraviolet absorbent may change. In contrast, in the case where the ultraviolet absorbent is a compound not having both hydroxy group and a carbonyl group per molecule, the alkoxide compound is less likely to form a complex with the ultraviolet absorbent, and the ultraviolet absorbent is likely to exhibit inherent UV-absorption properties thereof. It should be noted that the ultraviolet absorbent may include either a hydroxy group or a carbonyl group in one molecule.

The ultraviolet absorbent is selected desirably in view of absorbing light in a desired wavelength range, having compatibility with a particular solvent, dispersing well in the light-absorbing composition, particularly, the curable resin or the like, having excellent environmental durability, etc. Examples of the ultraviolet absorbent include a benzophenone-based compound, a benzotriazole-based compound, a salicylic-acid-based compound, and a triazine-based compound. For example, Tinuvin PS, Tinuvin 99-2, Tinuvin 234, Tinuvin 326, Tinuvin 329, Tinuvin 900, Tinuvin 928, Tinuvin 405, and Tinuvin 460 can be used as the ultraviolet absorbent. These are ultraviolet absorbents manufactured by BASF, and Tinuvin is a registered trademark.

An amount of the ultraviolet absorbent in the light absorber is not limited to a particular value as long as the transmission spectrum of the light absorber 10 at an incident angle of 0° satisfies the requirements (I) to (V). A high absorbing ability can be exhibited even with a small amount of the ultraviolet absorbent. A ratio of the amount of the ultraviolet absorbent to the amount of the copper component in the light absorber 10 is, for example, 0.01 to 1, desirably 0.02 to 0.5, and more desirably 0.07 to 0.14 on a mass basis. A ratio of the amount of the ultraviolet absorbent to the amount of the phosphorus component in the light absorber is, for example, 0.02 to 2, desirably 0.04 to 1, and more desirably 0.12 to 0.26 on a mass basis.

The light-absorbing dispersion includes at least the light-absorbing compound (light absorbent) and a solvent. The light-absorbing dispersion may include a dispersant that contributes to dispersion of the light-absorbing compound. For example, the light-absorbing composition is obtained by adding an appropriate curable resin to the light-absorbing dispersion. For example, the light absorber 10 is produced by curing this light-absorbing composition.

The light-absorbing dispersion may include, for example, a solvent, the light-absorbing compound including the phosphonic acid and the copper component, and the phosphoric acid ester that contributes to dispersion of the light-absorbing compound in the solvent. The light-absorbing dispersion is substantially free of a curable resin. Because of this, there is no concern for curing of the dispersion during distribution of the light-absorbing dispersion. A person who intends to obtain the light absorber 10 can prepare the light-absorbing composition being a precursor of the light absorber 10 by mixing the light-absorbing dispersion and a separately prepared curable resin. Ease of the concern for curing of the material or increase in viscosity of the material during product distribution can also contribute to a longer shelf life or pot life of the dispersion.

Saying that the light-absorbing dispersion is substantially free of a curable resin means that the light-absorbing dispersion is not solidified by applying external energy to the light-absorbing dispersion by heating, application of an electromagnetic wave (including visible light, ultraviolet light, etc.), or the like. The light-absorbing dispersion may include a curable resin in such a small amount that the light-absorbing dispersion will not be solidified. The type of energy applied for curing of a curable resin mixed with the light-absorbing dispersion is not limited. Application of such energy includes heating and application of an electromagnetic wave such as light. For example, curing the resin by leaving it alone (leaving it to stand still) at ordinary room temperature (20° C. to 28° C.) is broadly interpreted as heating and is included also in application of energy. The light-absorbing dispersion is free of a curable resin, such as curable epoxy resin, phenolic resin, melamine resin, unsaturated polyester resin, alkyd resin, silicone resin, polyurethane resin, polyimide resin, acrylic resin, urea resin, or a modified product thereof. The curable acrylic resin includes modified acrylate resins such as epoxy acrylate and urethane acrylate. Furthermore, when the light-absorbing dispersion is substantially free of a curable resin, at least curing does not occur. Some curable resins are supplied in two parts, such as a combination of a main part and a curing agent or a combination of a main part and a catalyst. Considering that there is such a curable resin set, the light-absorbing dispersion being a specific example of the present invention includes a system including a main part and not including a curing agent or a catalyst.

The light-absorbing dispersion may include the first phosphonic acid and the second phosphonic acid. The light-absorbing compound including the alkylphosphonic acid has high absorbency in a wavelength range from 800 nm to 1200 nm within a near-infrared region, while the light-absorbing compound including the arylphosphonic acid has high light absorbency at a wavelength near 680 nm. The light-absorbing dispersion's including both the first phosphonic acid and the second phosphonic acid is meaningful in many cases. In the light-absorbing dispersion, the light-absorbing compound including the arylphosphonic acid and the copper component and the light-absorbing compound including the alkylphosphonic acid and the copper component may be included in the solvent free of the above curable resin.

The solvent included in the light-absorbing dispersion is not limited to a particular solvent. The solvent included in the light-absorbing dispersion is, for example, an organic solvent. The solvent included in the light-absorbing dispersion can be tetrahydrofuran (THF), toluene, acetone, acetonitrile, acetylacetone, allyl alcohol, benzene, benzyl alcohol, butanol, methyl ethyl ketone, butyl alcohol, epichlorohydrin, cresol, methanol, ethanol, or a mixture of two or more organic solvents selected from these, but is not limited to one of these.

The light-absorbing dispersion has, for example, a particular transmission spectrum. The light-absorbing dispersion has, for example, a transmission spectrum satisfying the following requirements (i), (ii), (iii), and (iv). This transmission spectrum can be obtained, for example, by normalizing a transmission spectrum to have a transmittance of 20% at a wavelength of 700 nm, the transmission spectrum being obtained by allowing light with wavelengths of 300 nm to 1600 nm to incident on the light-absorbing dispersion.
(i) An average transmittance T^{A}_{DP(460-600)} in a wavelength range of 460 nm to 600 nm is 85% or more.
(ii) A shorter cut-off wavelength λ^{H}_{DP(S)} that lies in a wavelength range of 350 nm to 450 nm and at which a transmittance is 50% is 380 nm to 420 nm.
(iii) A longer cut-off wavelength λ^{H}_{DP(L)} that lies in a wavelength range of 600 nm to 700 nm and at which a transmittance is 50% is 600 nm to 650 nm.
(iv) An average transmittance T^{A}_{DP(725-1000)} in a wavelength range of 725 nm to 1000 nm is 5% to 20%.

The light-absorbing compound dispersion is produced, for example, by dispersing the light-absorbing compound in toluene at a given concentration. Then, the dispersion is put in a commercially-available quartz cell to produce a measurement workpiece, which is measured for its transmission spectrum with a spectrophotometer. A base line is subtracted to obtain a transmission spectrum of the light-absorbing compound dispersion. Then, normalization of the transmittance in the measurement wavelength range is performed such that the transmittance at a wavelength of 700 nm will be 20%. It should be noted that the base line is determined, for example, in such a manner that a transmission spectrum of toluene not including the light-absorbing compound is measured in an identical quartz cell with a spectrophotometer.

When the transmission spectrum of the light-absorbing compound dispersion satisfies the above requirements (i) to (iv), light absorbers produced by curing light-absorbing compositions obtained by mixing this dispersion with various curable resins or optical filters including such light absorbers are likely to satisfy the above requirements (I) to (V).

The shorter cut-off wavelength λ^{H}_{DP(S)} may be in a range of 390 nm to 410 nm. The longer cut-off wavelength λ^{H}_{DP(L)} may be in a range of 610 nm to 640 nm or 615 nm to 635 nm.

The transmission spectrum of the light-absorbing compound dispersion may satisfy the following requirements (v), (vi), (vii), and (viii).
(v) A wavelength λ^{min}_{DP(700-1500)} of a minimum transmittance in a wavelength range of 700 nm to 1500 nm is in a range of 750 nm to 950 nm.
(vi) In a wavelength range of 600 nm to 1500 nm, a difference λ^{range(20)}_{DP(600-1500)} between the longest wavelength and the shortest wavelength of wavelengths at which the transmittance is 20% is 350 nm to 600 nm.
(vii) In the wavelength range of 600 nm to 1500 nm, a difference λ^{range(50)}_{DP(600-1500)} between the longest wavelength and the shortest wavelength of wavelengths at which a the transmittance is 50% is 600 nm to 750 nm.
(viii) In a wavelength range of 350 nm to 700 nm, a difference λ^{range(50)}_{DP(350-700)} between the longest wavelength and the shortest wavelength of wavelengths at which the transmittance is 50% is 180 nm to 280 nm.

When the transmission spectrum of the light-absorbing compound dispersion satisfies the above requirements (v) to (viii), light absorbers produced by curing light-absorbing compositions obtained by mixing this dispersion with various binders or optical filters including such light absorbers are more likely to satisfy the above requirements (I) to (V).

The wavelength λ^{min}_{DP(700-1500)} may be in a range of 800 nm to 900 nm or a range of 820 nm to 880 nm. The difference λ^{range(20)}_{DP(600-1500)} may be 400 nm to 550 nm. The difference λ^{range(50)}_{DP(600-1500)} may be 620 nm to 720 nm or 630 nm to 710 nm. The difference λ^{range(50)}_{DP(350-700)} may be 190 nm to 260 nm or 200 nm to 250 nm.

A thickness of the light absorber 10 of the optical filter 1a is not limited to a particular thickness. The thickness of the light absorber 10 is, for example, approximately 200 nm or 200 nm or less, and thus the light absorber 10 makes a great contribute to production of a low-profile apparatus. On the other hand, the optical filter 1b including the substrate 20 is likely to have a high stiffness or high mechanical strength, which enables provision of a rigid optical filter.

The substrate 20 is not limited to a particular substrate. The substrate 20 may be selected, for example, so that the optical filter 1b will satisfy the above requirements (I) to (V) or the optical filter 1b will further satisfy the requirements (VI) and (VII) in addition to the above requirements (I) to (V). The substrate 20 may be selected so that the optical filter 1b will satisfy the above requirements (1-i) to (1-iv) and (2-i) to (2-iv).

A shape of the substrate 20 is not limited to a particular shape. As shown in FIG. 1B, the substrate may be in the shape of a flat plate. It is thought that, in this case, it is easy to apply the light-absorbing composition to the substrate 20 used as a support of the optical filter 1b and the optical filter 1b also has great versatility as an optical filter. Alternatively, the substrate 20 may include a curved face or may have a projecting or recessed face. The shape of the substrate 20 may be a shape other than a plate shape. For example, examples of the substrate 20 include optical elements such as a lens, a polarizer, a prism, a reflective element, and a diffraction grating. These optical elements can have a face including a curved face and a flat face. Furthermore, other examples of the substrate 20 include a photoelectric conversion element such as a photodiode or a phototransistor, an image sensor in which a lot of photoelectric conversion elements such as CCDs or CMOSs are arranged, an image sensor equivalent to such an image sensor, and a microlens array integrated with an imaging device. Yet another example of the substrate 20 is a display unit such as a display of a mobile personal digital assistant.

The substrate 20 may be transparent. When the substrate 20 may be transparent, a transmission spectrum of the optical filter 1b including the light absorber 10 and the substrate 20 is more reflective of a transmission spectrum of the light absorber 10. In a transmission spectrum of a 3 mm-thick flat plate made of the same material as the transparent substrate 20, the transmittance in a wavelength range of 360 nm to 900 nm may be 90% or more, or the transmittance in a wavelength range of 350 nm to 1200 nm may be 85% or more. The substrate 20 having such transparency is typically a glass substrate. The substrate 20 can be made of, for example, a silicate glass such as soda-lime glass or borosilicate glass or a phosphate or fluorophosphate glass containing a coloring component such as Cu or Co. The phosphate or fluorophosphate glass containing the coloring component is, for example, an infrared-absorbing glass, and has light-absorption properties in itself. In the case of using the light absorber together with a substrate made of an infrared-absorbing glass, an optical filter having desired optical properties can be produced by adjusting the light-absorption properties and transmission spectra of the light-absorber and the substrate, and the flexibility in designing optical filters is high.

A typical example of the substrate 20 is a resin substrate. A resin included in the resin substrate is a cycloolefin resin such as a norbornene resin, a polyarylate resin, an acrylic resin, a modified acrylic resin, a polyimide resin, a polyetherimide resin, a polyolefin resin, a polysulfone resin, a polyethersulfone resin, a polycarbonate resin, or a silicone resin. Resins have extremely high processability and high formability, compared to glasses. Therefore, substrates, such as optical elements, having various shapes are easily prepared with resins.

An antireflection film or a reflection reduction film may be provided on a surface of the light absorber 10 or an optical filter including the light absorber 10 in order to reduce the reflectance or increase the transmittance of light with a given wavelength. FIG. 1C to FIG. 1D each show an example of an optical filter including the light absorber 10 and antireflection films.

As for an optical filter 1c shown in FIG. 1C, an antireflection film 31a is disposed on one principal surface of the light absorber 10, and an antireflection film 32a is disposed on the other principal surface. The antireflection film 31a and the antireflection film 32a are each an antireflection film having a single-layer structure.

As for an optical filter 1d shown in FIG. 1D, an antireflection film 31b is disposed on one principal surface of the light absorber 10, and an antireflection film 32b is disposed on the other principal surface. The antireflection film 31b and the antireflection film 32b are each an antireflection film having a double-layer structure.

As for an optical filter 1e shown in FIG. 1E, an antireflection film 31c is disposed on one principal surface of the light absorber 10, and an antireflection film 32c is disposed on the other principal surface. The antireflection film 31c and the antireflection film 32c are each an antireflection film having a triple-layer structure.

As for an optical filter 1f shown in FIG. 1F, an antireflection film 31d is disposed on one principal surface of the light absorber 10, and an antireflection film 32d is disposed on the other principal surface. The antireflection film 31d and the antireflection film 32d are each an antireflection film having a multilayer structure including three or more layers.

When an optical filter includes a transparent substrate and the light absorber 10 formed on the transparent substrate, an antireflection film may be formed on each of the surface of the light absorber 10 and a surface of the transparent substrate, the surface not being in contact with the light absorber 10.

The antireflection film can increase the transmittance of the light absorber 10 or an optical filter including the light absorber 10 in a transmission wavelength band which is a wavelength band of light capable of passing through the light absorber 10 or the optical filter. The transmission wavelength band may be a wavelength band in which the transmittance is 50% or more in a transmission spectrum of the light absorber 10 or an optical filter including the light absorber 10.

When the antireflection film is formed on the light absorber 10, an optical filter including the light absorber 10, or a transparent substrate (i.e., D263 T eco by Corning Incorporated) for supporting them, the reflectance in a wavelength range of 400 nm to 600 nm is, for example, 1% or less, desirably 0.5% or less, and more desirably 0.25% or less for light with wavelengths from 300 nm to 1200 nm, the light being incident at an incident angle of 5°.

When the antireflection film is formed on the light absorber 10, an optical filter including the light absorber 10, and a transparent substrate for supporting them, an average reflectance in the wavelength range of 700 nm to 1200 nm is, for example, 1% or less, desirably 0.5% or less, and more desirably 0.25% or less for light with wavelengths from 300 nm to 1200 nm, the light being incident at an incident angle of 5°. Hence, a portion of light belonging to infrared light is less likely to be reflected to cause ghosting or flare in obtained images.

When light with wavelengths from 300 nm to 1200 nm is incident on an optical filter including the light absorber 10 and the antireflection film at an incident angle of 50°, the reflectance in the wavelength range of 400 nm to 600 nm is, for example, 3% or less, or desirably 1% or less. In addition, when light with wavelengths from 300 nm to 1200 nm is incident on the optical filter at an incident angle of 50°, the average reflectance in the wavelength range of 700 nm to 1200 nm is, for example, 3% or less, and desirably 1.5% or less. Hence, reflection of light is likely to be prevented even when the incident angle of light incident on the light absorber 10 or the optical filter including the light absorber 10 is large.

The antireflection film is not limited to a particular film. The antireflection film includes, for example, at least one layer selected from the group consisting of the following layers (a), (b), and (c). The antireflection film may include a combination of two or more of the layers.
(a) A layer formed by a sol-gel process using a reactive material including silicon
(b) A layer formed by a sol-gel process using a reactive material including silicon, the layer further including fine particles
(c) A layer formed by a physical film formation method such as vacuum deposition or sputtering

Regarding the above layers (a) and (b), the reactive material including silicon is not limited to a particular material, and a functional group in the reactive material is not limited to a particular functional group, either. The reactive material including silicon desirably includes a trifunctional silane such as methyltriethoxysilane (MTES) and a tetrafunctional silane such as tetraethoxysilane (TEOS). The tetrafunctional silane is important to form a coating film having a firm and dense structure. However, using the tetrafunctional silane alone can create disadvantages, for example, difficulty in controlling the reactivity, a narrow range of choices about porosity, and easy occurrence of cracking. Inclusion of the trifunctional silane as well as the tetrafunctional silane enhances the flexibility of the silica structure and improves the range of choices about porosity. That enables adjustment of the refractive index (adjustment of the porosity) for the antireflection film. Additionally, occurrence of cracking is likely to be reduced. An organic functional group of the trifunctional silane is basically not limited to a particular one. A trifunctional silane having a methyl group is desirably used in combination with the tetrafunctional silane. This is because a homogeneous liquid and a homogeneous coating film can be easily formed in this case. Amounts of the trifunctional silane and the tetrafunctional silane are desirably in the following range: the amount of the trifunctional silane to the amount of the tetrafunctional silane=5:1 to 1:3. In this case, a firmer structure can be formed with the trifunctional silane while occurrence of cracking in the antireflection film is reduced by the tetrafunctional silane. The reactive material including silicon may include a bifunctional silane. A raw material of the above layer (a) may include a component other than the components involved in the sol-gel process.

The above trifunctional silane is not limited to a particular silane. Examples of the trifunctional silane include methyltriethoxysilane, methyltrimethoxysilane, ethyltriethoxysilane, ethyltrimethoxysilane, propyltriethoxysilane, propyltrimethoxysilane, butyltriethoxysilane, butyltrimethoxysilane, pentyltrimethoxysilane, pentyltriethoxysilane, hexyltriethoxysilane, and hexyltrimethoxysilane. The trifunctional silane may be a trifunctional silane having an alkyl group directly bonded to a silicon atom (Si). The tetrafunctional silane is not limited to a particular silane. Examples of the tetrafunctional silane include tetraethoxysilane, tetramethoxysilane, tetrapropoxysilane, and tetrabutoxysilane.

Hydrolysis of any of the silane compounds forms a hydrolysate of a silane compound including a silanol group. Then, the trifunctional silane and the tetrafunctional silane respectively turn into (poly)silsesquioxane and silica by polycondensation of the hydrolysate. Since refractive indices of (poly)silsesquioxane and silica are as low as approximately 1.46, a layer having a low refractive index can be formed. Hence, a layer including at least one selected from the group consisting of (poly)silsesquioxane and silica is suitable as a layer included in the antireflection film of the light absorber 10 or an optical filter including the light absorber 10.

To form the above layers (a) and (b), for example, a coating film of a liquid composition including the reactive material including silicon can be formed and fired. The firing of the coating film is performed, for example, at a temperature in a range of 60° C. to 170° C., desirably 60° C. to 150° C., and more desirably 60° C. to 115° C.

Regarding the above layer (b), a particulate compound can be included in the layer including the reactive material including silicon, the hydrolysate of the reactive material, or the polycondensation product of the hydrolysate. The particulate compound is, for example, fine particles including silica, titania, zirconia, or alumina. The material of the fine particles has a refractive index of, for example, 1.40 to 2.55. The material of fine particles is desirably silica. In the layer including at least one selected from the group consisting of silica and (poly)silsesquioxane, the silica and the (poly)silsesquioxane function as binders surrounding the fine particles. That increases a bonding strength acting between the fine particles and the binder via the silanol group or the like, and thus enhancement of the reliability such as the weather resistance can be expected.

The fine particles included in the above layer (b) may be fine hollow particles. Since the fine hollow particle has an empty space inside, the refractive index thereof tends to be very low. The refractive index of the fine hollow particle is, for example, 1.02 to 1.50.

An average particle diameter of the fine hollow particles is, for example, 5 nm to 200 nm. The average particle diameter of the fine hollow particles can be determined, for example, by measuring the maximum diameters of 50 or more particles randomly selected on a cross-section of the above layer (b) with a microscope such as an optical microscope, an electron microscope, or a metallurgical microscope and calculating the arithmetic mean of the maximum diameters.

An amount of the fine hollow particles in the above layer (b) is, for example, 5 to 95% on a mass basis.

The above layer (b) including the fine hollow particles is likely to have a very low refractive index. The refractive index of the above layer (b) including the fine hollow particles is, for example, 1.00 to 1.45 (excluding 1.00). For example, THRULYA 4110 manufactured by JGC Catalyst and Chemicals Ltd. can be used as the fine hollow particles.

The layer including at least one selected from the group consisting of silica and (poly)silsesquioxane and the fine hollow particles tends to have a low refractive index, compared with the layer including at least one selected from the group consisting of silica and (poly)silsesquioxane and not including the fine hollow particles. The antireflection film may be configured such that the layer including at least one selected from the group consisting of silica and (poly)silsesquioxane and fine hollow particles, the layer including at least one selected from the group consisting of silica and (poly)silsesquioxane and not including the fine hollow particles, and the light absorber 10 or an optical filter including the light absorber 10 are disposed in this order. In this case, the reflection prevention effect can be enhanced sometimes.

The fine particles included in the above layer (b) may be fine solid particles. The fine solid particle has a refractive index of, for example, 1.25 to 1.65, and more suitably 1.30 to 1.65. The layer (b) including the fine solid particles has a refractive index of, for example, 1.10 to 1.55. An average particle diameter of the fine solid particles is, for example, 2 nm to 200 nm. The average particle diameter of the fine solid particles can be determined, for example, in the same manner as for the average particle diameter of the fine hollow particles. For example, SNOWTEX MP-2040 manufactured by Nissan Chemical Industries, Ltd. can be used as the fine solid particles.

The above layer (b) may include fine particles having a relatively high refractive index. In this case, the layer (b) is likely to have a high refractive index. In this case, the fine particles may include at least one material selected from the group consisting of TiO₂ (titanium oxide; refractive index: 2.33 to 2.55), Ta₂O₅ (tantalum oxide; refractive index: 2.16), Nb₂O₅ (niobium oxide; refractive index: 2.33), and Si₃N₄ (silicon nitride; refractive index: 2.02). The fine particles may include two or more materials. The layer (b) desirably includes fine particles of, for example, TiO₂. In this case, the layer (b) is likely to have a high refractive index, and a high-refractive-index film, which contrasts with, for example, a low-refractive-index film including hollow silica (SiO₂) particles, can be obtained. The refractive index of the layer (b) including fine TiO₂ particles is, for example, 1.50 to 2.30. Incidentally, as for an example of the above layer (b), it is possible to control the refractive index of the film by adjusting an amount of the fine particles or the like relative to amounts of the components included in the film.

An average particle diameter of the fine TiO₂ particles is, for example, 2 nm to 200 nm. The average particle diameter of the fine TiO₂ particles can be determined, for example, in the same manner as for the average particle diameter of the fine hollow particles. An amount of the fine TiO₂ particles in the layer (b) is, for example, 2% to 50% on a mass basis. For example, NS405 manufactured by Tayca Corporation, TTO-51A manufactured by ISHIHARA SANGYO KAISHA, LTD., or the like can be used as the fine TiO₂ particles.

The fine particles included in the above layer (b) may be subjected to a surface treatment using a coupling agent such as a silane coupling agent or a titanium coupling agent before mixing the binder or a matrix. In this case, the adherence or the wettability is likely to be enhanced between the binder or the matrix and the fine particles. The above surface treatment is effective also when fine particles other than those made of TiO₂ or SiO₂ are used.

For example, the antireflection film may be composed of a combination of a low-refractive-index layer, a middle-refractive-index layer, and a high-refractive-index layer. The low-refractive-index layer is a layer, for example, including at least one selected from the group consisting of silica and (poly)silsesquioxane and the fine hollow particles. The middle-refractive-index layer is a layer including at least one selected from the group consisting of silica and (poly)silsesquioxane and not including fine hollow particles. The high-refractive-index layer is a layer including at least one selected from the group consisting of silica and (poly)silsesquioxane and the fine TiO₂ particles. The antireflection film may be configured taking account of conditions, such as thicknesses of the layers, the numbers of layers, and a repetitive pattern of the layers, for combining the low-refractive-index layer, the middle-refractive-index layer, and the high-refractive-index layer in the antireflection film.

The above layer (c) can be formed by a physical method such as vacuum deposition including ion assist deposition (IAD), sputtering, or ion plating. These methods are collectively called deposition. By deposition, a layer including a dielectric and a metal oxide can be obtained as the layer (c). A material of the layer (c) formed by deposition is not limited to a particular material. The material of the layer (c) includes, for example, at least one inorganic compound selected from the group consisting of SiO₂, TiO₂, Ta₂O₃, SnO₂, In₂O₃, Nb₂O₅, Si₃N₄, TiNₓ, and MgF₂. The layer (c) may be a layer in which two or more inorganic compounds selected from these inorganic compounds are mixed in a given proportion.

The layer (c) may have a single-layer structure including only one single material, or may have a multilayer structure in which two or more layers made of different materials (which may be material mixtures) selected from the above inorganic compounds are stacked. When the antireflection film is a multilayer film, the antireflection film may be formed, for example, by adjusting thicknesses of layers and the number of layers and alternatively stacking the layers. The layers are, for example, a layer made of a relatively-high-refractive-index material such as TiO₂, Ta₂O₃, or Nb₂O₅ or a mixture of such materials and a layer made of a relatively-low-refractive-index material such as SiO₂ or MgF₂ or a mixture of such materials.

An optical filter including the light absorber 10 may be included in an ambient light sensor. An ambient light sensor is a device that is mounted in an apparatus for detection of the brightness, the hue, or the like around the apparatus. An ambient light sensor included in an apparatus recognizes an attribute of light around the apparatus and, for example, automatically adjusts the brightness or the like of a display device, such as a display, mounted in the apparatus. Ambient light sensors are sometimes called luminance sensors or illuminance sensors.

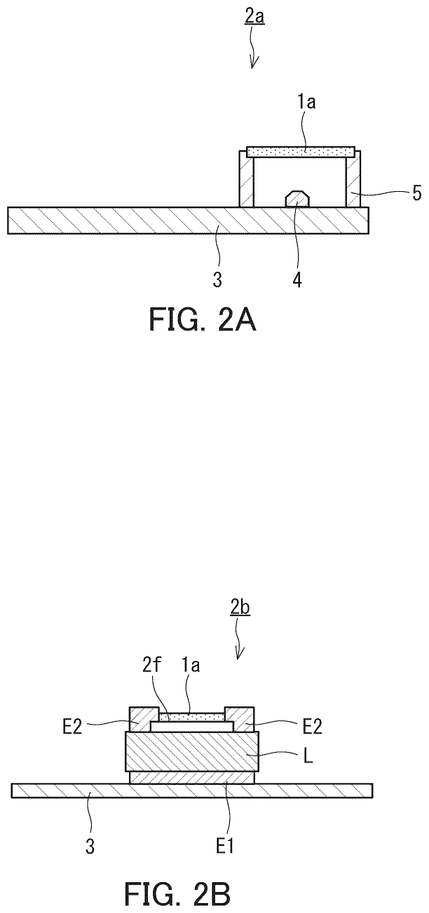

FIG. 2A is a cross-sectional view showing an example of an ambient light sensor. As shown in FIG. 2A, an ambient light sensor 2 includes, for example, an electric circuit board 3, a photoelectric conversion element 4, a housing 5, and the optical filter 1a. The ambient light sensor 2 detects, for example, an attribute of light belonging to the visible region among attributes of light around an apparatus including the ambient light sensor 2. The electric circuit board 3 supports the ambient light sensor 2, and electrically connects the ambient light sensor 2 to a nearby device. The photoelectric conversion element 4 is disposed on the electric circuit board 3 and includes, for example, an element such as a photodiode or a phototransistor. The housing 5 is disposed on the electric circuit board 3 and surrounds the photoelectric conversion element 4. The optical filter 1a is disposed, for example, in front of the photoelectric conversion element 4 so as to block a portion of light traveling toward the photoelectric conversion element 4. The optical filter 1a blocks, for example, a portion of light belonging to ultraviolet light or infrared light. The optical filter 1a is supported by the housing 5.

An ambient light sensor may include, as shown in FIG. 2A, an optical filter including the light absorber 10, or may include, for example, as shown in FIG. 2B, an integrated photoelectric conversion element in which the light absorber 10 and a photoelectric conversion element are integrated. A photoelectric conversion element 2b shown in FIG. 2B includes a light-receiving face 2f and the light absorber 10. In the photoelectric conversion element 2b, the light-receiving face 2f and the light absorber 10 are disposed in this order. The photoelectric conversion element 2b is an integrated photoelectric conversion element. The integrated photoelectric conversion element is obtained, for example, by applying the above light-absorbing composition to a surface of the light-receiving face (a pane) of the photoelectric conversion element and curing the applied light-absorbing composition to form the light absorber 10. Such a photoelectric conversion element eliminates the need for a light absorber separated from the photoelectric conversion element. The ambient light sensor as described above can block, for example, light outside the visible region, such as a portion of light belonging to ultraviolet light or infrared light by absorption by means of the light absorber 10. That can significantly enhance the usability of the ambient light sensor as an ambient light sensor specialized in detection of light in an approximate visible region. Moreover, simplification of a supply chain for distribution of a product can be expected.

In the photoelectric conversion element 2b, for example, a first electrode E1 and a photoelectric conversion layer L are stacked in this order on the electric circuit board 3. Additionally, a second electrode E2, the light-receiving face 2f, and the light absorber 10 are disposed on the photoelectric conversion layer L.

In order to reduce the reflectance or increase the transmittance of light with a given wavelength, the antireflection film or a reflection reduction film may be provided on a surface of the light absorber 10 to be mounted in an ambient light sensor or an optical filter to be mounted in an ambient light sensor, the optical filter including the light absorber 10.

An optical filter including the light absorber 10 may be included in an imaging apparatus or a camera module. An imaging apparatus or a camera module includes, for example, an image sensor, an electric circuit board, a lens system, and an optical filter including the light absorber 10. In the image sensor, for example, a lot of photoelectric conversion elements such as CCDs or CMOSs are arranged. The electric circuit board electrically connects the image sensor to an external device. The lens system includes one lens group or two or more lens groups for condensing light from a subject or the like on the image sensor and forming an image. The optical filter including the light absorber 10 can block a portion of light belonging to ultraviolet light and infrared light.

For example, in the imaging apparatus in which an optical filter including the light absorber 10 is mounted, a portion of light belonging to ultraviolet light and infrared light is blocked by absorption and light belonging to the visible region passes through the optical filter toward the image sensor. In the case where an optical filter has a function of reflecting a portion of light by means of a dielectric multilayer film or the like, a portion of light reflected by the optical filter is reflected on a surface of a lens system disposed in front of the optical filter inside a housing to reach a light-receiving face of an imaging device, or a portion of such reflected light projects a shadow of a diaphragm or the shape of the diaphragm on the light-receiving face of the imaging device. Consequently, a phenomenon, such as ghosting or flare, that spoils contrast comes to the fore. On the other hand, the imaging apparatus in which an optical filter including the light absorber 10 is mounted reduces occurrence of such a phenomenon and ghosting, flare, or the like is less conspicuous in an image obtained with the imaging apparatus.

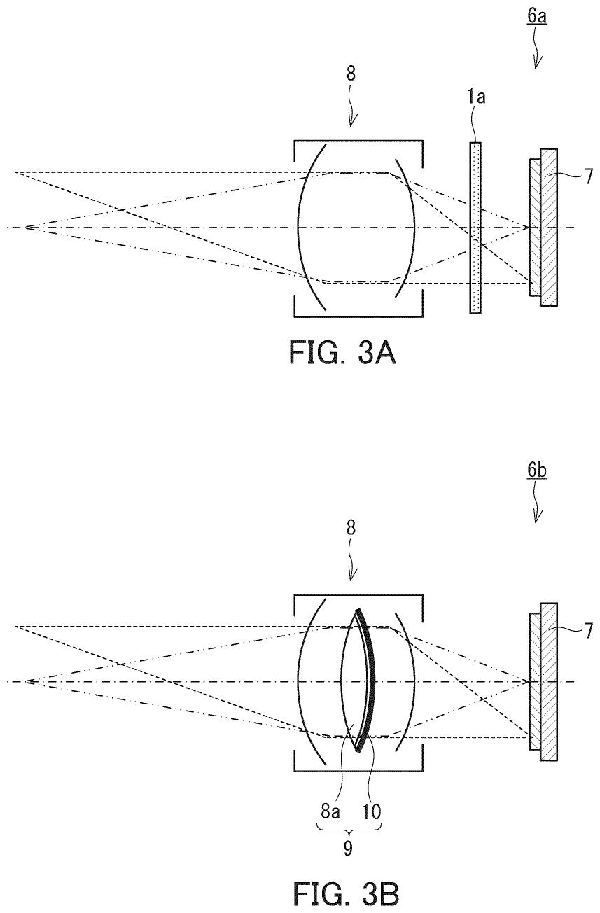

FIG. 3A shows an example of the imaging apparatus. This figure schematically shows the imaging apparatus. Only the elements necessary for description are schematically described, and other parts and elements are omitted. As shown in FIG. 3A, an imaging apparatus 6a includes an image sensor 7, a lens system 8, and the optical filter 1a. In the imaging apparatus 6a, the optical filter 1a is disposed, for example, between the image sensor 7 and the lens system 8 and just in front of the image sensor 7. The position of the optical filter is not limited to the position shown in FIG. 3A. The optical filter may be disposed on the subject side, i.e., in front of the lens system 8. In this case, the optical filter includes, for example, the light absorber 10 and a transparent dielectric substrate supporting the light absorber 10. When a rigid substrate, such as a glass substrate, is used as the transparent dielectric substrate, the optical filter can be expected to have a function as a protecting filter for protecting the imaging apparatus and the lens system from the outside.

FIG. 3B shows another example of the imaging apparatus. An imaging apparatus 6b is configured in the same manner as the imaging apparatus 6a, unless otherwise described. As shown in FIG. 3B, in the imaging apparatus 6a, the light absorber 10 is disposed on a surface of a lens 8a being part of the lens system 8. For example, by applying the above light-absorbing composition to the surface of the lens 8a and curing the applied light-absorbing composition, the light absorber 10 can be disposed such that an interface is formed between the light absorber 10 and the lens 8a. In this case, without a light-absorbing optical filter provided separately from the lens system 8, the lens system 8 can have desired light blocking properties, and therefore significant simplification of assembling or manufacturing of the imaging apparatus can be expected. The above-described lens 8a formed integrally with the light absorber 10 or a lens system including the above-described lens 8a may be distributed. The antireflection film or a reflection reduction film may be formed on a surface of the light absorber 10. In that case, reflected light from the surface of the light absorber 10 is likely to be reduced, and transmitted light in the visible region is likely to increase. In the imaging apparatus 6b, the position of the light absorber 10 is not limited to the position thereof shown in FIG. 3B.

Some lens systems of imaging apparatuses include a group of lenses, the group being formed of two or more lenses whose surfaces are bonded to each other. An adhesive or a curable resin can be used to bond the lenses. Though not illustrated, such an adhesive or the like for bonding the lenses may include the above light-absorbing composition, the above light-absorbing dispersion, or the above light-absorbing compound. In that case, the light absorber 10 is less likely to be affected by an external environment of the lens system, and protection of the light absorber 10 or the components included in the light absorber 10 are expected. If the curable resin is selected so that the refractive indices of the light absorber 10 and the lens forming an interface with the light absorber 10 will be approximately the same, there is an advantage in that reflection at the interface between the light absorber 10 and the lens can be reduced so significantly that no antireflection coating is necessary.

### EXAMPLES

The present invention will be described in more detail by examples. The present invention is not limited to the examples given below.

### Example 1

An amount of 4.500 g of copper acetate monohydrate and 240 g of tetrahydrofuran (THF) were mixed, and the mixture was stirred for three hours to obtain a copper acetate solution. To the obtained copper acetate solution was then added 1.77 g of PLYSURF A208N (manufactured by DKS Co., Ltd.) which is a phosphoric acid ester compound, and the mixture was stirred for 30 minutes to obtain a solution A. An amount of 40 g of THF was added to 0.552 g of phenylphosphonic acid, and the mixture was stirred for 30 minutes to obtain a solution B. An amount of 40 g of THF was added to 3.308 g of 4-bromophenylphosphonic acid, and the mixture was stirred for 30 minutes to obtain a solution C. An amount of 40 g of THF was added to 0.588 g of n-butylphosphonic acid, and the mixture was stirred for 30 minutes to obtain a solution D. An amount of 6.68 g of methyltriethoxysilane (manufactured by Shin-Etsu Chemical Co., Ltd.; product name: KBE-13) and 2.19 g of tetraethoxysilane (manufactured by KISHIDA CHEMICAL Co., Ltd.; special grade) were further added to a liquid mixture prepared by mixing the solutions A, B, C, and D, and the resulting mixture was stirred for one minute to obtain a solution E. To the solution E was then added 120 g of toluene, and the mixture was stirred at room temperature for one minute to obtain a solution F. The solution F was put in a flask and subjected to solvent removal using a rotary evaporator (manufactured by Tokyo Rikakikai Co., Ltd.; product code: N-1110SF) under heating by means of an oil bath (manufactured by Tokyo Rikakikai Co., Ltd.; product code: OSB-2100). The temperature of the oil bath was controlled to 105° C. The solution having undergone the solvent removal was collected from the flask. A light-absorbing compound dispersion (solution G) according to Example 1 including a phosphonic acid and a copper component was obtained in this manner.

Table 1 shows raw materials and amounts of the raw materials added for production of the light-absorbing compound according to Example 1 and the light-absorbing compound dispersion according to Example 1. Table 2 shows ratios between amounts of the phosphonic acid, the copper component, and the phosphoric acid ester included in the light-absorbing compound dispersion on a molar basis or a mass basis. It should be noted that the light-absorbing compound dispersion according to Example 1 includes a light-absorbing compound to be included in the light absorber and is free of a curable resin and a curing catalyst.

An amount of 8.98 g of a silicone resin (manufactured by Shin-Etsu Chemical Co., Ltd.; product name: KR-300), 0.16 g of a catalyst (manufactured by Shin-Etsu Chemical Co., Ltd.; product name: CAT-AC), 6.96 g of methyltriethoxysilane (manufactured by Shin-Etsu Chemical Co., Ltd.; product name: KBE-13) as a trifunctional alkoxysilane, 4.05 g of a tetraethoxysilane (manufactured by KISHIDA CHEMICAL Co., Ltd.; special grade) as a tetrafunctional alkoxysilane, and 4.07 g of dimethyldiethoxysilane (DMDES) (manufactured by Shin-Etsu Chemical Co., Ltd.; product name: KBE-22) as a bifunctional alkoxysilane were mixed and then stirred for 30 minutes to obtain a liquid curable resin (solution H) to be used as a binder or a matrix resin.

Next, the solution G being the light-absorbing compound dispersion and the solution H being a curable resin were mixed and then stirred for 30 minutes to obtain a light-absorbing composition according to Example 1. Table 1 shows raw materials of the curable resin, the curing catalyst, and the alkoxysilane and amounts of the raw materials added for production of the light-absorbing composition according to Example 1.

An amount of 0.1 g of an anti-smudge surface coating agent (manufactured by DAIKIN INDUSTRIES, LTD.; product name: OPTOOL DSX; concentration of active ingredient: 20 mass %) and 19.9 g of a hydrofluoroether-containing solution (manufactured by 3M Company; product name: Novec 7100) were mixed and then stirred for five minutes to prepare a fluorine treatment agent (concentration of active ingredient: 0.1 mass %). This fluorine treatment agent was applied to one principal surface of a borosilicate glass substrate (manufactured by SCHOTTAG; product name: D263 T eco) having dimensions of 130 mm×100 mm×0.70 mm. The glass substrate was left at room temperature for 24 hours to dry the coating film made of the fluorine treatment agent, and the glass surface was then wiped lightly with a dust-free cloth impregnated with Novec 7100 to remove an excess of the fluorine treatment agent. A fluorine-treated substrate was thus produced.

The light-absorbing composition according to Example 1 was applied with a dispenser to an 80 mm×80 mm region at a central portion of the one principal surface of the fluorine-treated substrate to form a coating film. After the coating film was sufficiently dried at room temperature, the substrate and the coating film were put in an oven and heated sufficiently from room temperature to 85° C. to sufficiently carry out a reaction of the alkoxysilane and evaporate the solvent. After that, the coating film was left to stand still in an environment at a temperature of 85° C. and a relative humidity of 85% for post curing for additional 24 hours, and the reaction was completed. Finally, the coating film was peeled off the fluorine-treated substrate to obtain a light absorber according to Example 1. This light absorber can be used as an optical filter when used to exhibit its function by itself.
(Measurement of Transmission Spectra and Reflection Spectra of Light Absorber)

Transmission spectra were measured for the light absorber according to Example 1 at incident angles of 0°, 40°, 50°, 60°, and 70° using an ultraviolet-visible-near-infrared spectrophotometer V-770 manufactured by JASCO Corporation and equipped with a transmitted light measurement attachment. An environment around the measurement target had a temperature of 22 to 25° C. during the transmittance spectrum measurement, unless otherwise specified. Furthermore, the attachment of the ultraviolet-visible-near-infrared spectrophotometer V-770 was replaced with a reflected light measurement attachment, with which reflection spectra of the light absorber according to Example 1 at incident angles of 5°, 40°, 50°, 60°, and 70° were measured. An environment around the measurement target had a temperature of 22 to 25° C. during the transmittance spectrum measurement, unless otherwise specified.

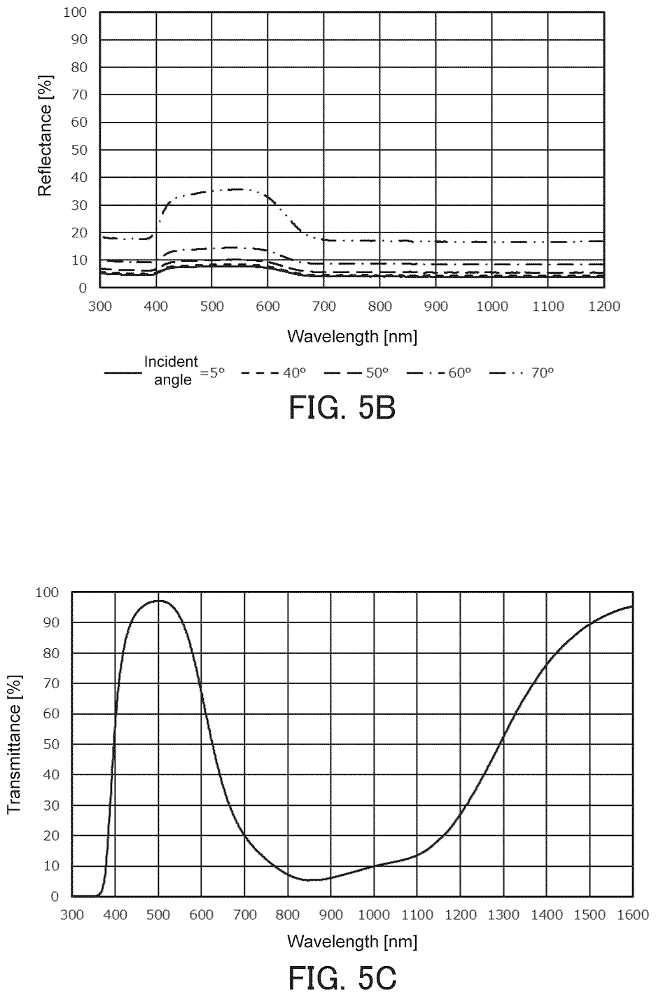

FIG. 5A shows the transmission spectra of the light absorber according to Example 1 at the incident angles. FIG. 5B shows reflection spectra of the light absorber according to Example 1 at the incident angles. Table 3 shows properties of the light absorber according to Example 1 at incident angles of 0° and 5°, the properties corresponding to the above requirements (I) to (VII). Tables 4 and 5 show given properties at the incident angles.
(Measurement of Transmission Spectrum of Light-Absorbing Compound Dispersion)

An appropriate amount of toluene was added to the light-absorbing compound dispersion (solution G) according to Example 1 to adjusted a light-absorbing compound dispersion for optical property measurement. A concentration of the light-absorbing compound in the light-absorbing compound dispersion for optical property measurement was adjusted so that the transmittance at a wavelength of 700 nm would be around 20% in a transmission spectrum of the light-absorbing compound dispersion. The light-absorbing compound dispersion adjusted in this manner for optical property measurement was put in a quartz cell (manufactured by JASCO Corporation; product code: J/1/Q/1; optical path length: 1 mm; optical path width: 10 mm; outer dimensions: 3.5 mm in length, 12.5 mm in width, 45 mm in height, 0.400 ml in volume). A primary transmission spectrum was measured for the light-absorbing compound dispersion according to Example 1 at an incident angle of 0° using an ultraviolet-visible-near-infrared spectrophotometer V-770 manufactured by JASCO Corporation and equipped with a transmitted light measurement attachment in which a quartz cell can be mounted. An environment around the measurement target had a temperature of 22 to 25° C. during the transmittance spectrum measurement, unless otherwise specified.

Furthermore, a transmission spectrum at an incident angle of 0° was measured in the same manner for a quartz cell charged only with toluene. A secondary transmission spectrum of the light-absorbing compound dispersion according to Example 1 was calculated by subtracting the transmission spectrum of toluene from the transmission spectrum of the light-absorbing compound dispersion. Then, the resulting transmission spectrum was normalized so that the transmittance at a wavelength of 700 nm would be 20%, and thereby an ultimate transmission spectrum of the light-absorbing compound dispersion was obtained. Note that the measurement for obtaining the transmission spectrum of the dispersion was performed for a wavelength range of 300 nm to 1600 nm.

FIG. 5C shows the transmission spectrum of the light-absorbing compound dispersion according to Example 1. Table 6 shows property values determined by the transmission spectrum of the light-absorbing compound dispersion.
(Measurement of Haze)

The haze of the light absorber according to Example 1 was measured using a haze meter (manufactured by MURAKAMI COLOR RESEARCH LABORATORY; product name: HM-65L2) according to Japanese Industrial Standards (JIS) K 7136: 2000. Table 3 shows a haze value (0.13%) of the light absorber according to Example 1.
(Measurement of Thickness)

A thickness of the light absorber according to Example 1 using a laser displacement meter LK-H008 manufactured by Keyence Corporation. Table 3 shows the thickness (192 μm) of the light absorber according to Example 1.

### Example 2

An amount of 4.500 g of copper acetate monohydrate and 240 g of tetrahydrofuran (THF) were mixed, and the mixture was stirred for three hours to obtain a copper acetate solution. To the obtained copper acetate solution was then added 1.73 g of PLYSURF A208N (manufactured by DKS Co., Ltd.) which is a phosphoric acid ester compound, and the mixture was stirred for 30 minutes to obtain a solution A. An amount of 40 g of THF was added to 0.572 g of phenylphosphonic acid, and the mixture was stirred for 30 minutes to obtain a solution B. An amount of 40 g of THF was added to 3.431 g of 4-bromophenylphosphonic acid, and the mixture was stirred for 30 minutes to obtain a solution C. An amount of 40 g of THF was added to 0.410 g of ethylphosphonic acid, and the mixture was stirred for 30 minutes to obtain a solution D. An amount of 6.93 g of methyltriethoxysilane (manufactured by Shin-Etsu Chemical Co., Ltd.; product name: KBE-13) and 2.27 g of tetraethoxysilane (manufactured by KISHIDA CHEMICAL Co., Ltd.; special grade) were further added to a liquid mixture prepared by mixing the solutions A, B, C, and D, and the resulting mixture was stirred for one minute to obtain a solution E. To the solution E was then added 120 g of toluene, and the mixture was stirred at room temperature for one minute to obtain a solution F. The solution F was put in a flask and subjected to solvent removal using a rotary evaporator (manufactured by Tokyo Rikakikai Co., Ltd.; product code: N-1110SF) under heating by means of an oil bath (manufactured by Tokyo Rikakikai Co., Ltd.; product code: OSB-2100). The temperature of the oil bath was controlled to 105° C. The solution having undergone the solvent removal was collected from the flask. A light-absorbing compound according to Example 2 including a phosphonic acid and a copper component and a light-absorbing compound dispersion (solution G) according to Example 2 were obtained in this manner.

Table 1 shows raw materials and amounts of the raw materials added for production of the light-absorbing compound according to Example 2 and the light-absorbing compound dispersion according to Example 2. Table 2 shows ratios between amounts of the phosphonic acid, the copper component, and the phosphoric acid ester included in the light-absorbing compound dispersion on a molar basis or a mass basis. It should be noted that the light-absorbing compound dispersion according to Example 2 includes a light-absorbing compound to be included in the light absorber and is free of a curable resin and a curing catalyst.

An amount of 8.98 g of a silicone resin (manufactured by Shin-Etsu Chemical Co., Ltd.; product name: KR-300), 0.16 g of a catalyst (manufactured by Shin-Etsu Chemical Co., Ltd.; product name: CAT-AC), 6.96 g of methyltriethoxysilane (manufactured by Shin-Etsu Chemical Co., Ltd.; product name: KBE-13) as a trifunctional alkoxysilane, 4.05 g of a tetraethoxysilane (manufactured by KISHIDA CHEMICAL Co., Ltd.; special grade) as a tetrafunctional alkoxysilane, and 4.07 g of dimethyldiethoxysilane (DMDES) (manufactured by Shin-Etsu Chemical Co., Ltd.; product name: KBE-22) as a bifunctional alkoxysilane were mixed and then stirred for 30 minutes to obtain a liquid curable resin H according to Example 2 to be used as a binder or a matrix resin. Next, the solution G according to Example 2 being a dispersion containing a light-absorbing compound and the solution H being a curable resin were mixed and then stirred for 30 minutes to obtain a light-absorbing composition according to Example 2.

Table 1 shows raw materials of the curable resin (a matrix or a binder), the curing catalyst, and the alkoxysilane and amounts of the raw materials added for production of the light-absorbing composition according to Example 2.

The light-absorbing composition according to Example 2 was applied with a dispenser to a 80 mm×80 mm region at a central portion of one principal surface of a borosilicate glass substrate (manufactured by SCHOTTAG; product name: D263 T eco) having dimensions of 130 mm×100 mm×0.70 mm to form a coating film. After the coating film was sufficiently dried at room temperature, the substrate and the coating film were put in an oven and heated sufficiently from room temperature to 85° C. to sufficiently carry out a reaction of the alkoxysilane and evaporate the solvent. After that, the coating film was left to stand still in an environment at a temperature of 85° C. and a relative humidity of 85% for post curing for additional 24 hours, and the reaction was completed. A light absorber according to Example 2 was integrated with the principal surface of the transparent glass. The light absorber according to Example 2 formed on the glass substrate can be used as an optical filter when allowed to exhibit its function by itself.

Transmission spectra, reflection spectra, a haze value, and a thickness of the light absorber according to Example 2 formed on the glass substrate and a transmission spectrum of the light-absorbing compound dispersion according to Example 2 were measured in the same manner as in Example 1. As for Example 2, the transmission spectra, the reflection spectra, and the haze value of the light absorber were measured for a laminate composed of the glass substrate and the light absorber.

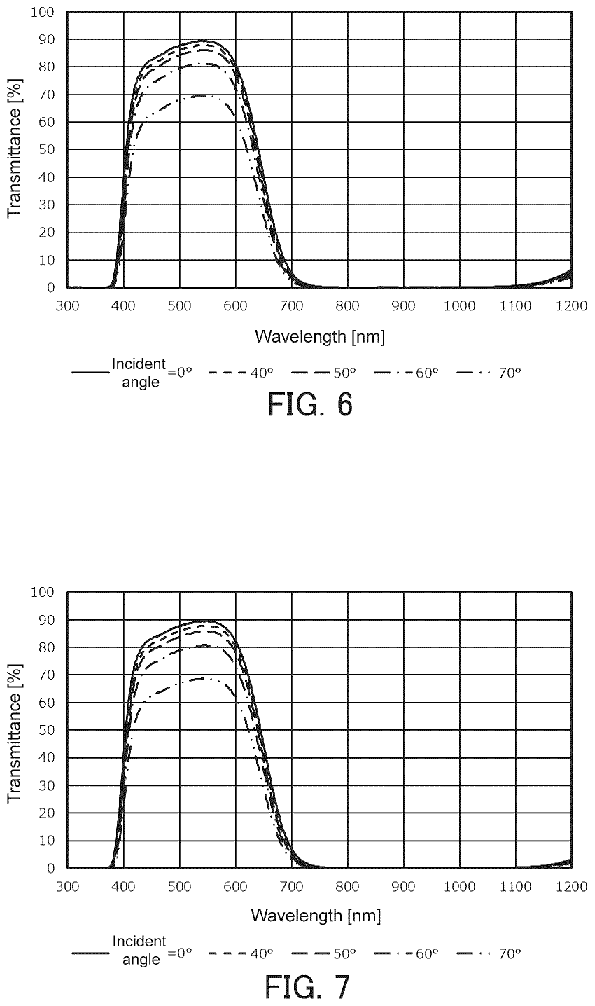

FIG. 6 shows the transmission spectra of the light absorber according to Example 2 formed on the glass substrate at the incident angles. Table 3 shows properties of the light absorber according to Example 2 formed on the glass substrate at incident angles of 0° and 5°, the properties corresponding to the above requirements (I) to (VII). Tables 4 and 5 show the given properties of the light absorber according to Example 2 formed on the glass substrate at the incident angles. Table 3 shows the haze value (0.13%) of the light absorber according to Example 2 formed on the glass substrate and the thickness (182 μm) of the light absorber according to Example 2.

### Example 3

A light-absorbing compound, a light-absorbing compound dispersion, a light-absorbing composition, and a light absorber according to Example 3 were produced in the same manner and under the same conditions as in Example 2, except that raw materials and the amounts of the raw materials added were adjusted as shown in Table 1, the light absorber being formed on a glass substrate. Transmission spectra, reflection spectra, a haze value, and a thickness of the light absorber according to Example 3 formed on the glass substrate and a transmission spectrum of the light-absorbing compound dispersion according to Example 3 were measured in the same manner and under the same conditions as in Example 1.

FIG. 7 shows the transmission spectra of the light absorber according to Example 3 at the incident angles. Table 3 shows properties of the light absorber according to Example 3 formed on the glass substrate at incident angles of 0° and 5°, the properties corresponding to the above requirements (I) to (VII). Tables 4 and 5 show the given properties of the light absorber according to Example 3 formed on the glass substrate at the incident angles. Table 3 shows the haze value (0.12%) of the light absorber according to Example 3 formed on the glass substrate and the thickness (180 μm) of the light absorber according to Example 3.

### Example 4

A light-absorbing compound, a light-absorbing compound dispersion, a light-absorbing composition, and a light absorber according to Example 4 were produced in the same manner and under the same conditions as in Example 2, except that raw materials and the amounts of the raw materials added were adjusted as shown in Table 1, the light absorber being formed on a glass substrate. Transmission spectra, reflection spectra, a haze value, and a thickness of the light absorber according to Example 4 formed on the glass substrate and a transmission spectrum of the light-absorbing compound dispersion according to Example 4 were measured in the same manner and under the same conditions as in Example 1.

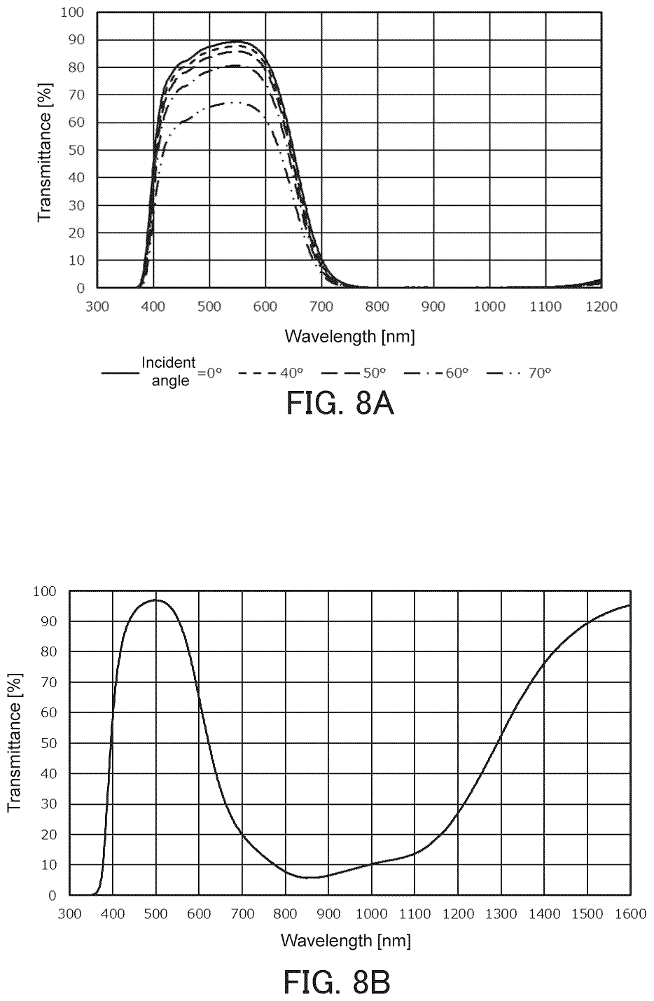

FIG. 8A shows the transmission spectra of the light absorber according to Example 4 formed on the glass substrate at the incident angles. FIG. 8B shows the transmission spectrum of the light-absorbing compound dispersion according to Example 4. Table 3 shows properties of the light absorber according to Example 4 formed on the glass substrate at incident angles of 0° and 5°, the properties corresponding to the above requirements (I) to (VII). Tables 4 and 5 show the given properties of the light absorber according to Example 4 formed on the glass substrate at the incident angles. Table 6 shows property values determined by the transmission spectrum of the light-absorbing compound dispersion. Table 3 shows the haze value (0.08%) of the light absorber according to Example 4 formed on the glass substrate and the thickness (171 μm) of the light absorber according to Example 4.

### Examples 5 to 12

Light-absorbing compounds, light-absorbing compound dispersions, light-absorbing compositions, and light absorbers according to Examples 5 to 12 were produced in the same manner and under the same conditions as in Example 1, except that raw materials and the amounts of the raw materials added were adjusted as shown in Table 1, the light absorbers being formed on glass substrates. Transmission spectra, reflection spectra, a haze value, and a thickness of each of the light absorbers according to Examples 5 to 12 formed on the glass substrates and transmission spectra of each of the light-absorbing compound dispersions according to Examples 5, 8, and 10 were measured in the same manner and under the same conditions as in Example 1.

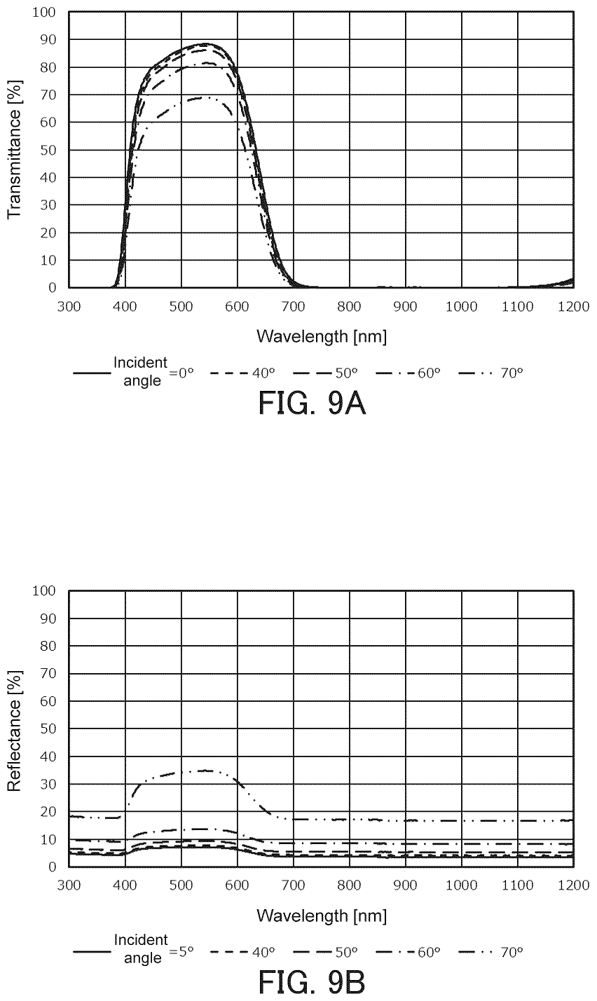

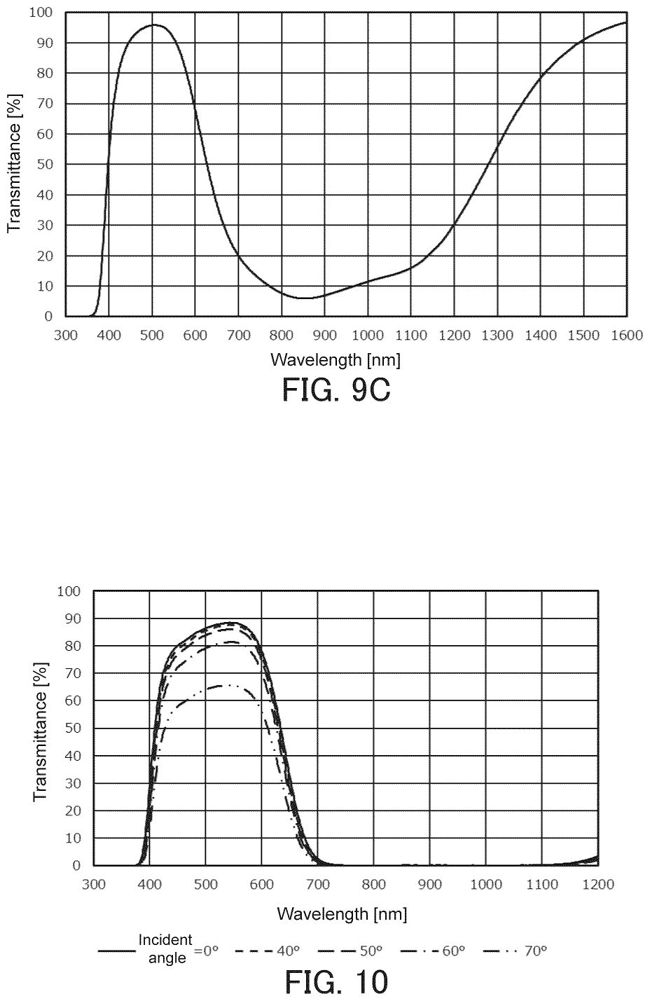

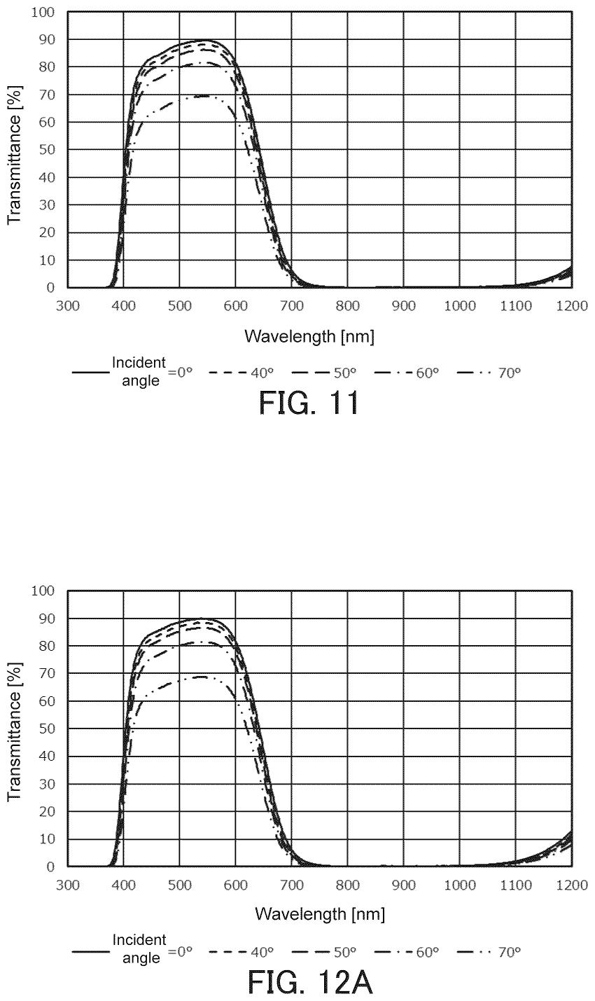

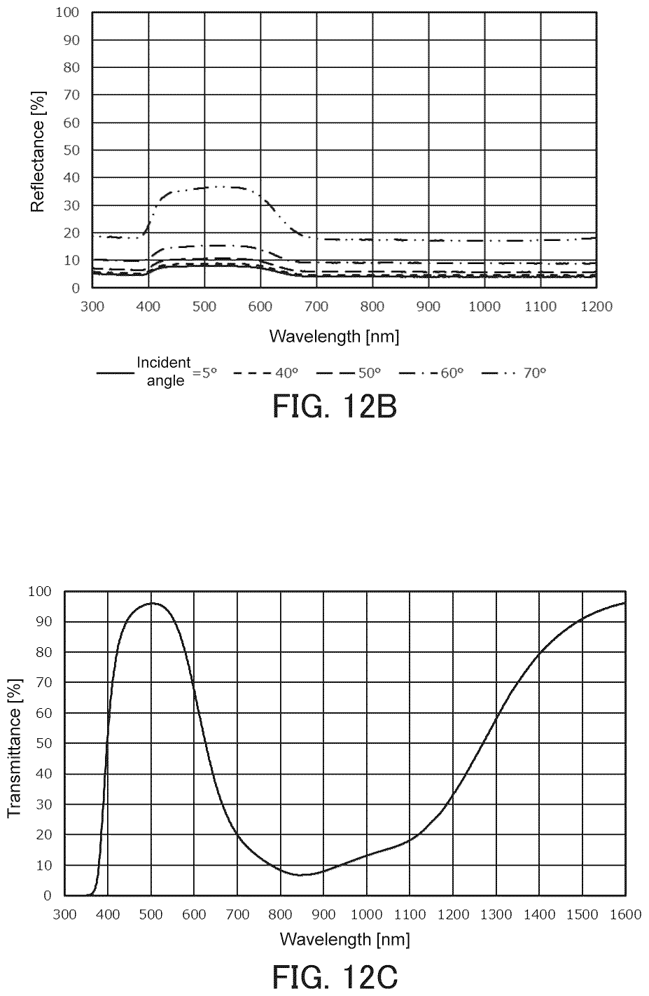

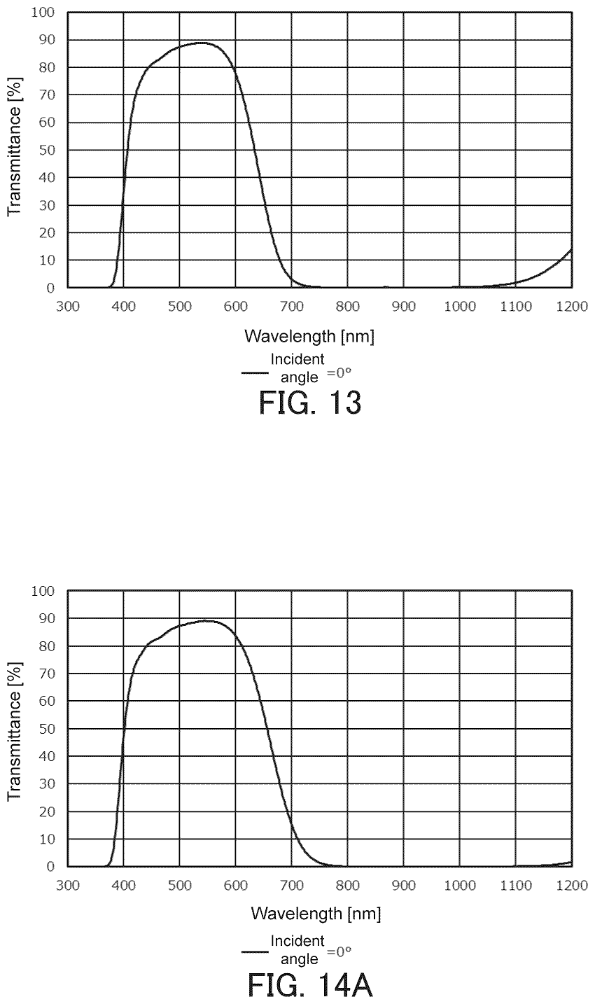

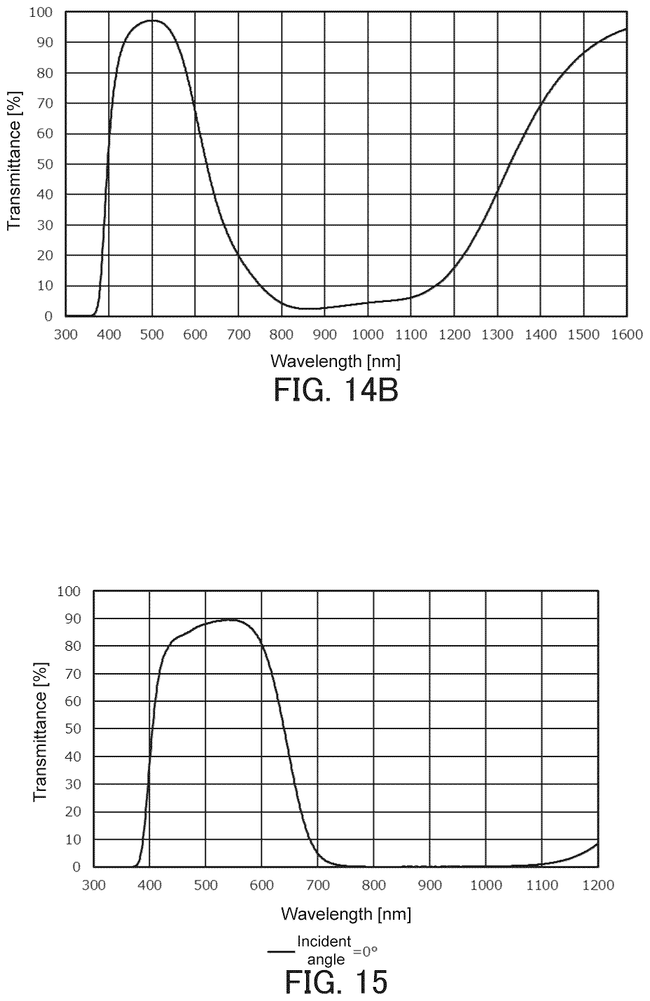

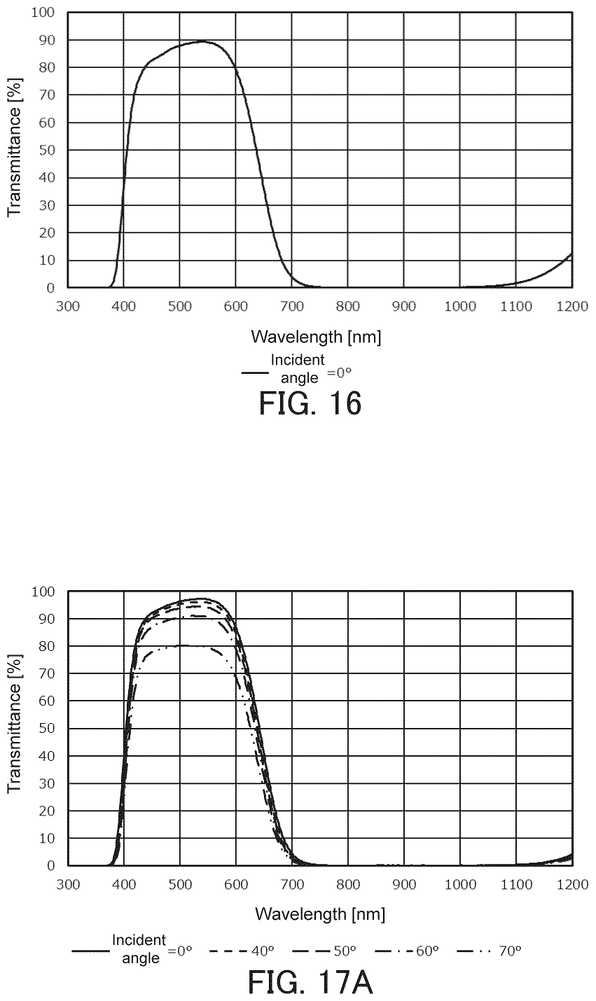

FIG. 9A, FIG. 9B, and FIG. 9C respectively show the transmission spectra of the light absorber according to Example 5 at the incident angles, the reflection spectra of the light absorber according to Example 5 at the incident angles, and the transmission spectrum of the light-absorbing compound dispersion according to Example 5. FIG. 10 shows the transmission spectra of the light absorber according to Example 6 at the incident angles. FIG. 11 shows the transmission spectra of the light absorber according to Example 7 at the incident angles. FIG. 12A, FIG. 12B, and FIG. 12C respectively show the transmission spectra of the light absorber according to Example 8 at the incident angles, the reflection spectra of the light absorber according to Example 8 at the incident angles, and the transmission spectrum of light-absorbing compound dispersion according to Example 8. FIG. 13 shows the transmission spectrum of the light absorber according to Example 9 at an incident angle of 0°. FIG. 14A and FIG. 14B respectively show the transmission spectrum of the light absorber according to Example 10 at an incident angle of 0° and the transmission spectrum of the light-absorbing compound dispersion according to Example 10. FIG. 15 shows the transmission spectrum of the light absorber according to Example 11 at an incident angle of 0°. FIG. 16 shows the transmission spectrum of the light absorber according to Example 12 at an incident angle of 0°.

Table 3 shows properties of the light absorbers according to Examples 5 to 12 at incident angles of 0° and 5°, the properties corresponding to the above requirements (I) to (VII). Tables 4 and 5 show the given properties of the light absorbers according to Examples 5 to 12 formed on the glass substrates at the incident angles. Table 6 shows property values determined by the transmission spectra of the light-absorbing compound dispersions according to Example 5, 8, and 10. Table 3 shows the haze values and the thicknesses (171 μm) of the light absorbers according to Examples 5 to 12.

### Example 13

A light-absorbing compound, a light-absorbing compound dispersion, a light-absorbing composition, and a light absorber according to Example 13 were produced in the same manner and under the same conditions as in Example 1, except that raw materials and the amounts of the raw materials added were adjusted as shown in Table 1.

An antireflection film was formed on each principal surface of the light absorber according to Example 13 to obtain an optical filter according to Example 13. Appropriate amounts of methyltriethoxysilane (MTES), tetraethoxysilane (TEOS), water for hydrolysis, and ethanol were mixed and stirred to produce a coating agent for antireflection film, the coating agent being a precursor of an antireflection film. The coating agent for antireflection film was applied to each principal surface of the light absorber according to Example 13. The application of the coating agent for antireflection film was performed for one principal surface of the light absorber at a time. Specifically, the coating agent for antireflection film was applied to one of the principal surfaces, and the surface with the coating agent for antireflection film was left to stand still for about one minute and confirmed that the surface was dry. The coating agent for antireflection film was then applied to the other principal surface in the same manner. Then, the light absorber was left to stand still in a constant-temperature chamber, and a heating treatment in an atmosphere at 85° C. for one hour was performed to remove the unnecessary solvent and a by-product by evaporation. An antireflection film was thereby provided on each principal surface of the light absorber. The antireflection films were porous, and each of the antireflection films on the principal surfaces was approximately 180 nm in thickness. An optical filter according to Example 13 including antireflection films was obtained in this manner.

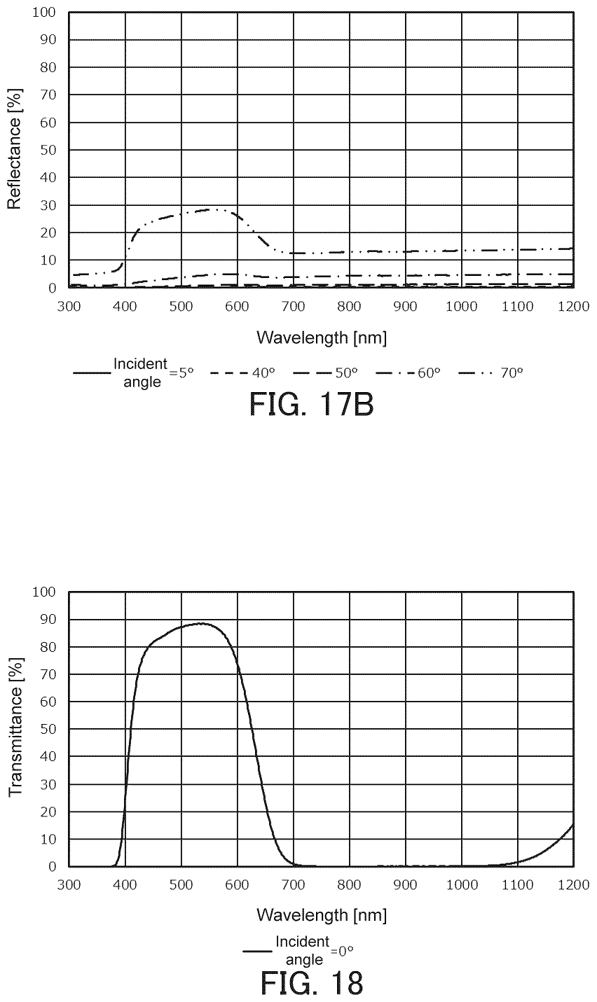

FIGS. 17A and 17B respectively show transmission spectra of the optical filter according to Example 13 at the incident angles and reflection spectra of the optical filter according to Example 13 at the incident angles. These transmission spectra and reflection spectra were obtained in the same manner and under the same conditions as in Example 1. Table 3 shows property values of the optical filter according to Example 13 at incident angles of 0° and 5°, the property values corresponding to the above requirements (I) to (VII). Tables 4 and 5 show the given properties of the optical filter according to Example 13 at the incident angles. Table 6 shows property values determined by the transmission spectrum of the light-absorbing compound dispersion according to Example 13. A transmission spectrum of the light-absorbing compound dispersion according to Example 13 was obtained in the same manner and under the same conditions as in Example 1. Table 3 shows the haze values of the optical filter according to Example 13 and the thickness of the light absorber according to Example 13.

### Comparative Examples 1 and 2

Light-absorbing compounds, light-absorbing compound dispersions, light-absorbing compositions, and light absorbers according to Comparative Examples 1 and 2 were produced in the same manner and under the same conditions as in Example 1, except that raw materials and the amounts of the raw materials added were adjusted as shown in Table 1. In Comparative Example 1, a ratio of the amount of the arylphosphonic acid to the amount of the alkylphosphonic acid is 9.414 on a molar basis. In Comparative Example 2, the ratio of the amount of the arylphosphonic acid to the amount of the alkylphosphonic acid is 12.983 on a molar basis. Transmission spectra, reflection spectra, haze values, and thicknesses of the light absorbers according to Comparative Examples 1 and 2 were measured in the same manner and under the same conditions as in Example 1.

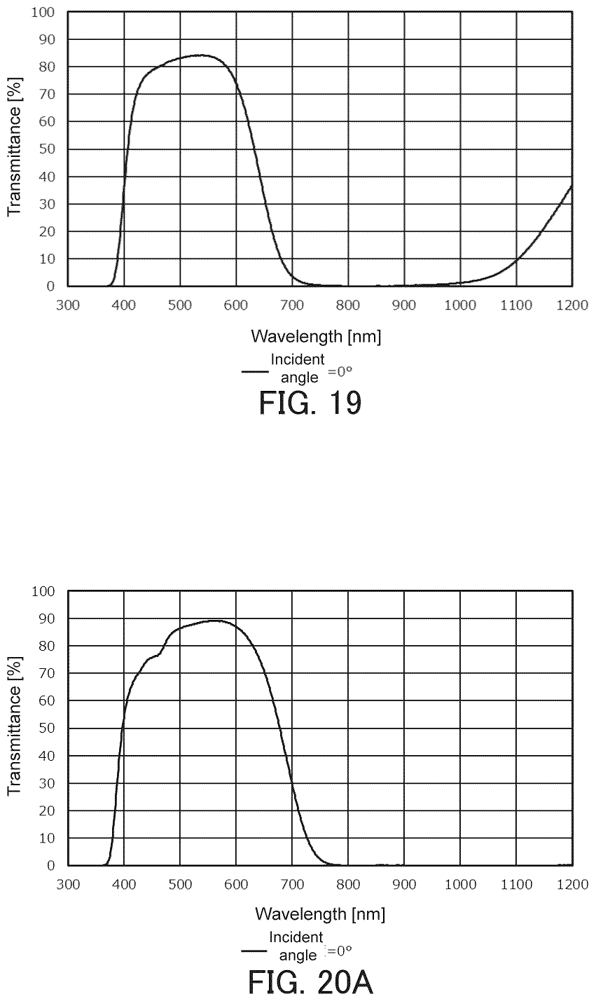

FIG. 18 and FIG. 19 respectively show the transmission spectra of the light absorbers according to Comparative Examples 1 and 2 at an incident angle of 0°. Table 3 shows property values of the optical filter according to Example 13 at incident angles of 0° and 5°, the property values corresponding to the above requirements (I) to (VII). Table 6 shows the haze values and the thicknesses of the light absorbers according to Comparative Examples 1 and 2. The haze values of the light absorbers according to Comparative Examples 1 and 2 are respectively 0.38 and 7.75.

### Reference Examples 1 and 2

Light-absorbing compounds, light-absorbing compound dispersions, light-absorbing compositions, and light absorbers according to Reference Examples 1 and 2 were produced in the same manner and under the same conditions as in Example 1, except that raw materials and the amounts of the raw materials added were adjusted as shown in Table 1. In Reference Examples 1 and 2, the ratio of the amount of the arylphosphonic acid to the amount of the alkylphosphonic acid is 1.620 on a molar basis. Transmission spectra, reflection spectra, haze values, and thicknesses of the light absorbers according to Reference Examples 1 and 2 were measured in the same manner and under the same conditions as in Example 1.

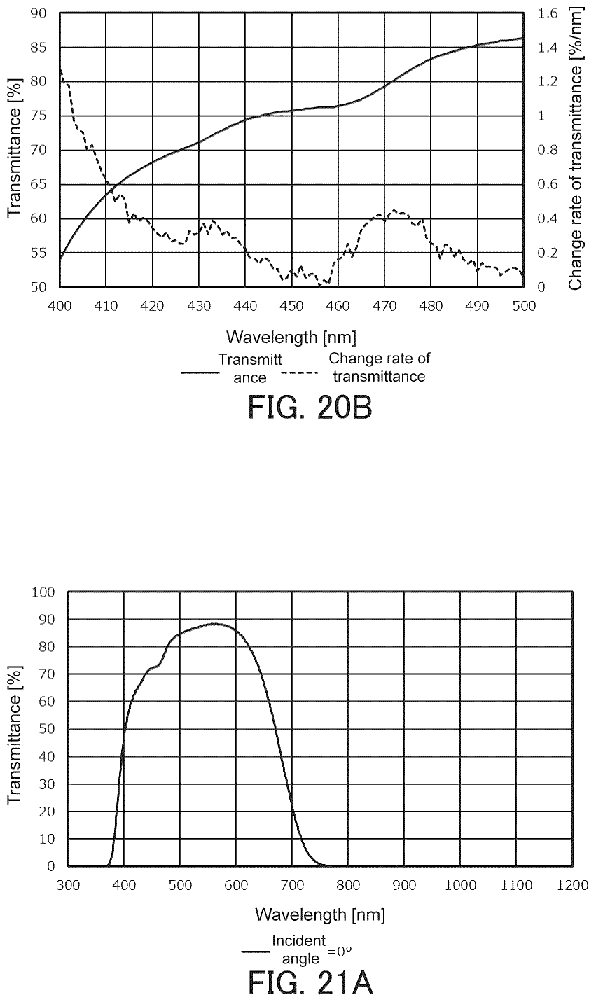

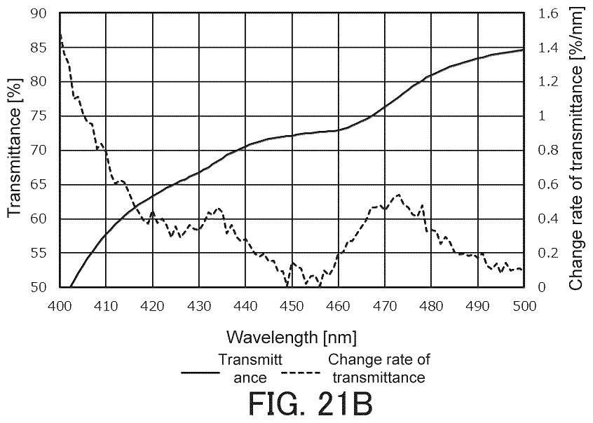

FIG. 20A and FIG. 21A respectively show the transmission spectra of the light absorbers according to Reference Examples 1 and 2 at an incident angle of 0°. FIG. 20B and FIG. 21B show the transmission spectra of the light absorbers according to Reference Examples 1 and 2, respectively, at an incident angle of 0° in a wavelength range of 400 nm to 500 nm and the change rates dT/dλ of the transmittance with respect to the wavelength. In each of the transmission spectra of the light absorbers according to Reference Examples 1 and 2, a plateau is observed in a wavelength range of 420 nm to 480 nm. The minimum, namely 0.1 [%/nm] or less, of the change rate of the transmittance with respect to the wavelength in the wavelength range of 420 nm to 480 nm is in a wavelength range of 440 nm to 460 nm. A difference between the maximum and the minimum of the change rate of the transmittance with respect to the wavelength in the wavelength range of 420 nm to 480 nm exceeds 0.4 [%/nm].

Table 3 shows property values of the optical filters according to Reference Examples 1 and 2 at incident angles of 0° and 5°, the property values corresponding to the above requirements (I) to (VII). Additionally, Table 3 shows haze values and thicknesses of the light absorbers according to Reference Examples 1 and 2. The haze values of Reference Examples 1 and 2 are respectively 0.14 and 0.16.

TABLE 1

| | Light-absorbing compound [g] | | | | |
|---|---|---|---|---|---|
| | | Phosphonic acid | | | |
| | | Arylphosphonic acid | | | |
| | | | 4- | 4- | |
| | Copper | Phenyl- | Bromophenyl- | Fluorophenyl- | 4-lodephenyl- |
| | acetate | phosphonic | phosphonic | phosphonic | phosphonic |
| | (anhydride) | acid | acid | acid | acid |
| Ex. 1 | 4.500 | 0.552 | 3.308 | 0 | 0 |
| Ex. 2 | 4.500 | 0.572 | 3.431 | 0 | 0 |
| Ex. 3 | 4.500 | 0.552 | 0 | 1.229 | 1.982 |
| Ex. 4 | 4.500 | 0.531 | 0 | 1.184 | 1.909 |
| Ex. 5 | 4.500 | 0.572 | 3.431 | 0 | 0 |
| Ex. 6 | 4.500 | 0.572 | 3.431 | 0 | 0 |
| Ex. 7 | 4.500 | 0.572 | 3.431 | 0 | 0 |
| Ex. 8 | 4.500 | 0.592 | 3.554 | 0 | 0 |
| Ex. 9 | 4.500 | 0.613 | 3.676 | 0 | 0 |
| Ex. 10 | 4.500 | 0.511 | 3.064 | 0 | 0 |
| Ex. 11 | 4.500 | 0.585 | 3.508 | 0 | 0 |
| Ex. 12 | 4.500 | 0.602 | 3.615 | 0 | 0 |
| Ex. 13 | 4.500 | 0.552 | 3.308 | 0 | 0 |
| Comp. | 4.500 | 0.634 | 3.799 | 0 | 0 |
| Ex. 1 | | | | | |
| Comp. | 4.500 | 0.654 | 3.921 | 0 | 0 |
| Ex. 2 | | | | | |
| Ref. Ex. | 4.500 | 0.409 | 2.451 | 0 | 0 |
| 1 | | | | | |
| Ref. Ex. | 4.500 | 0.409 | 2.451 | 0 | 0 |
| 2 | | | | | |

| | Light-absorbing compound [g] | | | | |
|---|---|---|---|---|---|
| | Phosphonic acid | | | | |
| | Alkylphosphonic acid | | | Alkoxysilane | |
| | n-Butyl- | Ethyl- | | Tetra- | Methyl- |
| | phosphonic | phosphonic | Phosphoric | ethoxy- | triethoxy- |
| | acid | acid | acid ester | silane | silane |
| Ex. 1 | 0.588 | 0 | 1.77 | 2.19 | 6.68 |
| Ex. 2 | 0 | 0.410 | 1.73 | 2.27 | 6.93 |
| Ex. 3 | 0.660 | 0 | 1.7 | 2.19 | 6.68 |
| Ex. 4 | 0 | 0.527 | 1.82 | 2.11 | 6.44 |
| Ex. 5 | 0.514 | 0 | 1.73 | 2.27 | 6.93 |
| Ex. 6 | 0.514 | 0 | 1.73 | 2.27 | 6.03 |
| Ex. 7 | 0.514 | 0 | 1.73 | 2.27 | 6.93 |
| Ex. 8 | 0.441 | 0 | 1.69 | 2.35 | 7.18 |
| Ex. 9 | 0.368 | 0 | 1.65 | 2.44 | 7.43 |
| Ex. 10 | 0.735 | 0 | 1.86 | 2.03 | 6.19 |
| Ex. 11 | 0.468 | 0 | 1.71 | 2.32 | 7.09 |
| Ex. 12 | 0.404 | 0 | 1.67 | 2.40 | 7.31 |
| Ex. 13 | 0.588 | 0 | 1.77 | 2.19 | 6.68 |
| Comp. | 0.294 | 0 | 1.61 | 2.52 | 7.67 |
| Ex. 1 | | | | | |
| Comp. | 0.220 | 0 | 1.57 | 2.60 | 7.92 |
| Ex. 2 | | | | | |
| Ref. Ex. | 1.102 | 0 | 2.06 | 1.62 | 4.95 |
| 1 | | | | | |
| Ref. Ex. | 1.102 | 0 | 2.06 | 1.62 | 4.95 |
| 2 | | | | | |

| | Matrix (binder) component [g] | | | | |
|---|---|---|---|---|---|
| | Silicone | | Alkoxysilane | | |
| | resin | Catalyst | Tetraethoxysilane | Methyltriethoxysilane | Dimethyldiethoxysilane |
| Ex. 1 | 8.98 | 0.16 | 4.05 | 6.96 | 4.07 |
| Ex. 2 | 8.98 | 0.16 | 4.05 | 6.96 | 4.07 |
| Ex. 3 | 8.98 | 0.16 | 4.05 | 6.96 | 4.07 |
| Ex. 4 | 8.98 | 0.16 | 4.05 | 6.96 | 4.07 |
| Ex. 5 | 0 | 0 | 4.05 | 6.96 | 4.07 |
| Ex. 6 | 3.59 | 0.16 | 4.05 | 6.96 | 4.07 |
| Ex. 7 | 12.57 | 0.44 | 0 | 0 | 4.65 |
| Ex. 8 | 8.98 | 0.16 | 4.05 | 6.96 | 4.07 |
| Ex. 9 | 8.98 | 0.16 | 4.05 | 6.96 | 4.07 |
| Ex. 10 | 8.98 | 0.16 | 4.05 | 6.96 | 4.07 |
| Ex. 11 | 8.98 | 0.16 | 4.05 | 6.96 | 4.07 |
| Ex. 12 | 8.98 | 0.16 | 4.05 | 6.96 | 4.07 |
| Ex. 13 | 8.98 | 0.16 | 4.05 | 6.96 | 4.07 |
| Comp. Ex. 1 | 8.98 | 0.16 | 4.05 | 6.96 | 4.07 |
| Comp. Ex. 2 | 8.98 | 0.16 | 4.05 | 6.96 | 4.07 |
| Ref. Ex. 1 | 8.98 | 0.16 | 4.05 | 6.96 | 4.07 |
| Ref. Ex. 2 | 8.98 | 0.16 | 4.05 | 6.96 | 4.07 |

TABLE 2

| | | | | Ratio of all | | | Ratio of | Ratio of |
|---|---|---|---|---|---|---|---|---|
| | Ratio of | | | phosphonic | Ratio of | Ratio of | phosphonic | phosphoric |
| | arylphosphonic | Ratio of | Ratio of | acid to | arylphosphonic | alkylphosphonic | acid to | acid ester |
| | acid to | arylphosphonic | alkylphosphonic | copper | acid to | acid to | phosphoric | to copper |
| | alkylphosphonic | acid to copper | acid to copper | component | phosphoric | phosphoric acid | acid ester | component |
| | acid | component | component | (Molar | acid ester | ester | (Mass | (Mass |
| | (Molar basis) | (Molar basis) | (Molar basis) | basis) | (Mass basis) | (Mass basis) | basis) | basis) |
| Ex. 1 | 4.098 | 0.774 | 0.189 | 0.963 | 2.181 | 0.332 | 2.513 | 1.236 |
| Ex. 2 | 4.857 | 0.803 | 0.165 | 0.968 | 2.314 | 0.237 | 2.551 | 1.208 |
| Ex. 3 | 3.651 | 0.774 | 0.212 | 0.986 | 2.214 | 0.388 | 2.602 | 1.187 |
| Ex. 4 | 3.509 | 0.746 | 0.212 | 0.958 | 1.991 | 0.290 | 2.281 | 1.271 |
| Ex. 5 | 4.862 | 0.803 | 0.165 | 0.968 | 2.314 | 0.297 | 2.611 | 1.208 |
| Ex. 6 | 4.862 | 0.803 | 0.165 | 0.968 | 2.314 | 0.297 | 2.611 | 1.208 |
| Ex. 7 | 4.862 | 0.803 | 0.165 | 0.968 | 2.314 | 0.297 | 2.611 | 1.208 |
| Ex. 8 | 5.869 | 0.831 | 0.142 | 0.973 | 2.453 | 0.261 | 2.714 | 1.180 |
| Ex. 9 | 7.276 | 0.860 | 0.118 | 0.978 | 2.599 | 0.223 | 2.822 | 1.152 |
| Ex. 10 | 3.037 | 0.717 | 0.236 | 0.953 | 1.922 | 0.395 | 2.317 | 1.299 |
| Ex. 11 | 5.460 | 0.821 | 0.150 | 0.971 | 2.394 | 0.274 | 2.667 | 1.194 |
| Ex. 12 | 6.516 | 0.846 | 0.130 | 0.975 | 2.525 | 0.242 | 2.767 | 1.166 |
| Ex. 13 | 4.098 | 0.774 | 0.189 | 0.963 | 2.181 | 0.332 | 2.513 | 1.236 |
| Comp. | 9.414 | 0.889 | 0.094 | 0.984 | 2.753 | 0.183 | 2.936 | 1.124 |
| Ex. 1 | | | | | | | | |
| Comp. | 12.983 | 0.918 | 0.071 | 0.988 | 2.914 | 0.140 | 3.054 | 1.096 |
| Ex. 2 | | | | | | | | |
| Ref. | 1.620 | 0.574 | 0.354 | 0.928 | 1.388 | 0.535 | 1.923 | 1.438 |
| Ex. 1 | | | | | | | | |
| Ref. | 1.620 | 0.574 | 0.354 | 0.928 | 1.388 | 0.535 | 1.923 | 1.438 |
| Ex. 2 | | | | | | | | |

TABLE 3

| | (I) | | | (IV) | | (VI) | | | |
|---|---|---|---|---|---|---|---|---|---|
| | Average | | | Average | (V) | Maximum | (VII) | | |
| | transmittance | | | transmittance | Average | reflectance | Maximum | | |
| | in | (II) | (III) | in | transmittance | in | reflectance in | | |
| | wavelength | Shorter cut- | Longer cut- | wavelength | in wavelength | wavelength | wavelength | | |
| | range of 460 | off | off | range of 300 | range of 750 | range of 300 | range of 700 | Haze | |
| | nm to 600 | wavelength | wavelength | nm to 380 | nm to 1100 | nm to 400 | nm to 1200 | value | |
| | nm [%] | [nm] | [nm] | nm [%] | nm [%] | nm [%] | nm [%] | [%] | Thickness |
| | T^{A}_{0deg(460-600)} | λ^{H}_{0deg(S)} | λ^{H}_{0deg(L)} | T^{A}_{0deg(300-380)} | T^{A}_{0deg(750-1000)} | R^{M}_{5deg(300-400)} | R^{M}_{5deg(700-1200)} | H_{A} | [μm] |
| Ex. 1 | 87.3 | 406 | 643 | 0.1 | 0.1 | 5.1 | 4.1 | 0.13 | 192 |
| Ex. 2 | 87.2 | 405 | 641 | 0.1 | 0.1 | 5.3 | 4.2 | 0.13 | 182 |
| Ex. 3 | 87.5 | 404 | 645 | 0.1 | 0.1 | 5.4 | 4.2 | 0.12 | 180 |
| Ex. 4 | 87.2 | 402 | 650 | 0.2 | 0.2 | 5.5 | 4.2 | 0.08 | 171 |
| Ex. 5 | 85.7 | 409 | 633 | 0.1 | 0.1 | 4.8 | 3.7 | 0.14 | 161 |
| Ex. 6 | 85.8 | 409 | 634 | 0.1 | 0.1 | 5.0 | 3.9 | 0.14 | 174 |
| Ex. 7 | 87.5 | 404 | 642 | 0.1 | 0.2 | 5.4 | 4.2 | 0.12 | 169 |
| Ex. 8 | 88.0 | 404 | 642 | 0.1 | 0.4 | 5.4 | 4.3 | 0.12 | 164 |
| Ex. 9 | 86.3 | 407 | 633 | 0.1 | 0.3 | 5.1 | 4.3 | 0.12 | 193 |
| Ex. 10 | 87.1 | 401 | 656 | 0.2 | 0.1 | 5.7 | 4.2 | 0.11 | 157 |
| Ex. 11 | 87.4 | 405 | 639 | 0.1 | 0.2 | 5.4 | 4.2 | 0.13 | 181 |
| Ex. 12 | 87.0 | 406 | 636 | 0.1 | 0.3 | 5.2 | 4.2 | 0.10 | 186 |
| Ex. 13 | 95.2 | 403 | 642 | 0.1 | 0.1 | 0.1 | 0.3 | 0.14 | 201 |
| Comp. | 85.6 | 410 | 626 | 0.1 | 0.2 | | | 0.38 | 250 |
| Ex. 1 | | | | | | | | | |
| Comp. | 82.1 | 407 | 633 | 0.1 | 1.3 | | | 7.75 | 183 |
| Ex. 2 | | | | | | | | | |
| Ref. Ex. | 86.5 | 397 | 678 | 0.7 | 0.1 | | | 0.14 | 186 |
| 1 | | | | | | | | | |
| Ref. Ex. | 85.0 | 402 | 670 | 0.3 | 0.1 | | | 0.16 | 235 |
| 2 | | | | | | | | | |

TABLE 4

| | Average transmittance in | | | | | | | | | | | | | | | Average transmittance in | | | | |
|---|---|---|---|---|---|---|---|---|---|---|---|---|---|---|---|---|---|---|---|---|
| | wavelength range of 460 nm to | | | | | | | | | | | | | | | wavelength range of 300 nm to | | | | |
| Incident | 600 nm [%] | | | | | Shorter cut-off wavelength [nm] | | | | | Longer cut-off wavelength [nm] | | | | | 380 nm [%] | | | | |
| angle | 0° | 40° | 50° | 60° | 70° | 0° | 40° | 50° | 60° | 70° | 0° | 40° | 50° | 60° | 70° | 0° | 40° | 50° | 60° | 70° |
| Ex. 1 | 87.3 | 85.9 | 83.9 | 79.3 | 65.9 | 406 | 408 | 409 | 412 | 420 | 643 | 641 | 638 | 634 | 621 | 0.1 | 0.1 | 0.1 | 0.1 | 0.2 |
| Ex. 2 | 87.2 | 85.6 | 83.7 | 78.9 | 67.5 | 405 | 407 | 408 | 411 | 418 | 641 | 638 | 636 | 631 | 620 | 0.1 | 0.1 | 0.1 | 0.1 | 0.1 |
| Ex. 3 | 87.5 | 85.8 | 83.6 | 78.7 | 66.8 | 404 | 406 | 407 | 410 | 417 | 645 | 642 | 639 | 635 | 623 | 0.1 | 0.1 | 0.1 | 0.1 | 0.1 |
| Ex. 4 | 87.2 | 85.5 | 83.5 | 78.4 | 65.3 | 402 | 405 | 406 | 409 | 418 | 650 | 647 | 644 | 639 | 625 | 0.2 | 0.1 | 0.1 | 0.1 | 0.2 |
| Ex. 5 | 85.7 | 84.9 | 83.2 | 78.6 | 66.3 | 409 | 411 | 412 | 415 | 424 | 633 | 631 | 629 | 625 | 614 | 0.1 | 0.1 | 0.1 | 0.1 | 0.1 |
| Ex. 6 | 85.8 | 84.8 | 83.2 | 78.5 | 63.2 | 409 | 411 | 412 | 415 | 427 | 634 | 631 | 629 | 625 | 610 | 0.1 | 0.1 | 0.1 | 0.1 | 0.1 |
| Ex. 7 | 87.5 | 86.0 | 84.0 | 79.3 | 67.4 | 404 | 406 | 407 | 410 | 417 | 642 | 639 | 637 | 633 | 621 | 0.1 | 0.1 | 0.1 | 0.1 | 0.1 |
| Ex. 8 | 88.0 | 86.4 | 84.5 | 79.4 | 66.9 | 404 | 406 | 407 | 410 | 417 | 642 | 639 | 637 | 632 | 620 | 0.1 | 0.1 | 0.1 | 0.1 | 0.1 |
| Ex. 13 | 95.2 | 94.0 | 92.3 | 88.9 | 78.3 | 403 | 405 | 406 | 408 | 410 | 642 | 639 | 637 | 633 | 626 | 0.1 | 0.1 | 0.1 | 0.1 | 0.1 |

| | Average transmittance in | | | | | Maximum reflectance in | | | | | Maximum reflectance in | | | | |
|---|---|---|---|---|---|---|---|---|---|---|---|---|---|---|---|
| | wavelength range of 750 nm to | | | | | wavelength range of 300 nm to | | | | | wavelength range of 700 nm to | | | | |
| Incident | 1100 nm [%] | | | | | 400 nm [%] | | | | | 1200 nm [%] | | | | |
| angle | 0° | 40° | 50° | 60° | 70° | 5° | 40° | 50° | 60° | 70° | 5° | 40° | 50° | 60° | 70° |
| Ex. 1 | 0.1 | 0.1 | 0.1 | 0.1 | 0.2 | 5.1 | 5.6 | 6.9 | 9.9 | 21.2 | 4.1 | 4.6 | 5.8 | 8.8 | 17.4 |
| Ex. 2 | 0.1 | 0.1 | 0.1 | 0.1 | 0.1 | 5.3 | 5.9 | 7.1 | 10.5 | 22.4 | 4.2 | 4.8 | 6.0 | 9.3 | 18.0 |
| Ex. 3 | 0.1 | 0.1 | 0.1 | 0.1 | 0.1 | 5.4 | 6.0 | 7.3 | 10.7 | 22.7 | 4.2 | 4.8 | 6.1 | 9.2 | 18.0 |
| Ex. 4 | 0.2 | 0.1 | 0.1 | 0.1 | 0.1 | 5.5 | 6.0 | 7.3 | 10.7 | 23.1 | 4.2 | 4.6 | 5.9 | 9.0 | 17.9 |
| Ex. 5 | 0.1 | 0.1 | 0.1 | 0.1 | 0.1 | 4.8 | 5.4 | 6.6 | 9.8 | 20.2 | 3.7 | 4.3 | 5.5 | 8.6 | 17.3 |
| Ex. 6 | 0.1 | 0.1 | 0.1 | 0.1 | 0.1 | 5.0 | 5.5 | 6.8 | 9.9 | 20.3 | 3.9 | 4.5 | 5.6 | 8.8 | 17.3 |
| Ex. 7 | 0.2 | 0.1 | 0.1 | 0.1 | 0.1 | 5.4 | 5.9 | 7.2 | 10.5 | 22.0 | 4.2 | 4.8 | 6.0 | 9.2 | 17.2 |
| Ex. 8 | 0.4 | 0.3 | 0.3 | 0.2 | 0.2 | 5.3 | 5.9 | 7.2 | 10.6 | 22.7 | 4.2 | 4.8 | 6.0 | 9.2 | 18.2 |
| Ex. 13 | 0.1 | 0.1 | 0.1 | 0.1 | 0.1 | 0.0 | 0.1 | 0.5 | 1.3 | 10.9 | 0.3 | 0.5 | 1.4 | 5.0 | 14.3 |

TABLE 5

| | λ^{H}_{40deg(S)}− | λ^{H}_{50deg(S)}− | λ^{H}_{60deg(S)}− | λ^{H}_{70deg(S)}− | λ^{H}_{0deg(L)}− | λ^{H}_{0deg(L)}− | λ^{H}_{0deg(L)}− | λ^{H}_{0deg(L)}− |
|---|---|---|---|---|---|---|---|---|
| | λ^{H}_{0deg(S)} | λ^{H}_{0deg(S)} | λ^{H}_{0deg(S)} | λ^{H}_{0deg(S)} | λ^{H}_{40deg(L)} | λ^{H}_{50deg(L)} | λ^{H}_{60deg(L)} | λ^{H}_{70deg(L)} |
| | [nm] | [nm] | [nm] | [nm] | [nm] | [nm] | [nm] | [nm] |
| Ex. 1 | 2 | 4 | 6 | 14 | 3 | 5 | 9 | 22 |
| Ex. 2 | 2 | 4 | 6 | 13 | 3 | 5 | 9 | 20 |
| Ex. 3 | 2 | 4 | 6 | 14 | 3 | 5 | 10 | 22 |
| Ex. 4 | 2 | 4 | 6 | 16 | 3 | 6 | 11 | 25 |
| Ex. 5 | 2 | 3 | 6 | 15 | 2 | 4 | 8 | 19 |
| Ex. 6 | 2 | 3 | 6 | 18 | 2 | 4 | 8 | 23 |
| Ex. 7 | 2 | 4 | 6 | 13 | 3 | 5 | 9 | 21 |
| Ex. 8 | 2 | 3 | 6 | 13 | 3 | 5 | 10 | 22 |
| Ex. 13 | 2 | 3 | 4 | 7 | 3 | 5 | 8 | 16 |

TABLE 6

| | | | | | Wavelength | |
|---|---|---|---|---|---|---|
| | | | | | at | |
| | Average | Maximum | | | which | |
| | transmittance | transmittance | | | transmittance | |
| | in | in | | | is | Minimum |
| | wavelength | wavelength | | | 20% | transmittance |
| | range | range | | | in | in wavelength |
| | of | of | | | wavelength | range of |
| | 460 | 725 | | | range | 700 |
| | nm | nm | | | of | nm |
| | to | to | Shorter | Longer | 350 | to |
| | 600 | 1000 | cut-off | cut-off | nm to | 1500 |
| | nm | nm | wavelength | wavelength | 450 nm | nm |
| | [%] | [%] | [nm] | [nm] | [nm] | [%] |
| Ex. 1 | 90.6 | 15.6 | 397 | 626 | 384 | 5.3 |
| Ex. 4 | 89.9 | 16.0 | 396 | 623 | 383 | 5.7 |
| Ex. 5 | 89.9 | 15.5 | 399 | 628 | 385 | 5.9 |
| Ex. 8 | 89.9 | 15.7 | 399 | 627 | 385 | 6.7 |
| Ex. 10 | 90.7 | 14.6 | 397 | 627 | 385 | 2.4 |

| | Wavelength | | | |
|---|---|---|---|---|
| | of | | | |
| | minimum | | | |
| | transmittance | | | Transmittance |
| | in | | | band |
| | wavelength | Absorption | Absorption | in |
| | range | band | band | which |
| | of | in | in | transmittance |
| | 700 | which transmittance | which transmittance | is |
| | nm | is 20% | is 50% | 50% |
| | to | or | or | or |
| | 1500 nm | less | less | more |
| | [nm] | [nm] | [nm] | [nm] |
| Ex. 1 | 850 | 461 | 666 | 229 |
| Ex. 4 | 850 | 46 | 669 | 227 |
| Ex. 5 | 850 | 439 | 652 | 229 |
| Ex. 8 | 849 | 421 | 643 | 228 |
| Ex. 10 | 850 | 522 | 703 | 230 |

1. Alight absorber comprising:
a copper component; and
a phosphonic acid,
the light absorber having a haze less than 0.20.

2. The light absorber according to claim 1, the phosphonic acid comprising:
a first phosphonic acid represented by the following formula (a), where R₁ is an alkyl group or a halogenated alkyl group in which at least one hydrogen atom in an alkyl group is substituted with a halogen atom; and
a second phosphonic acid represented by the following formula (b), where R₂ is an aryl group or a modified aryl group in which at least one hydrogen atom in an aryl group is substituted with a halogen atom, a nitro group, or a hydroxy group:

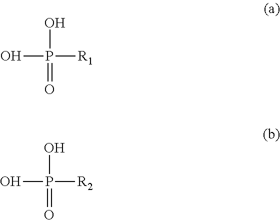

3. The light absorber according to claim 2, wherein
a ratio of an amount of the second phosphonic acid to an amount of the first phosphonic acid is 1.8 to 9 on a molar basis.

4. The light absorber according to claim 3, wherein
a ratio of a sum of the amount of the first phosphonic acid and the amount of the second phosphonic acid to an amount of the copper component is 0.3 to 3 on a molar basis.

5. The light absorber according to claim 4, wherein
a ratio of the amount of the first phosphonic acid to the amount of the copper component is 0.05 to 0.8 on a molar basis, and
a ratio of the amount of the second phosphonic acid to the amount of the copper component is 0.2 to 1.5 on a molar basis.

6. Alight-absorbing compound comprising:
a first light-absorbing compound comprising a copper component and a first phosphonic acid represented by the following formula (a), where R₁ is an alkyl group or a halogenated alkyl group in which at least one hydrogen atom in an alkyl group is substituted with a halogen atom; and
a second light-absorbing compound comprising a copper component and a second phosphonic acid represented by the following formula (b), where R₂ is an aryl group or a modified aryl group in which at least one hydrogen atom in an aryl group is substituted with a halogen atom, a nitro group, or a hydroxy group: 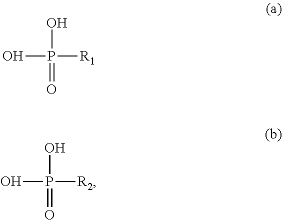
wherein
a dispersion of the light-absorbing compound is capable of transmitting a light with a second transmission spectrum for an incident light with wavelengths ranging from 300 nm to 1600 nm at an incident angle of 0°, and
the second transmission spectrum satisfies the following requirements (i), (ii), (iii), and (iv):
(i) an average transmittance in a wavelength range of 460 nm to 600 nm is 85% or more;
(ii) a shorter cut-off wavelength that lies in a wavelength range of 350 nm to 450 nm and at which a transmittance is 50% is in a range of 380 nm to 420 nm;
(iii) a longer cut-off wavelength that lies in a wavelength range of 600 nm to 700 nm and at which a transmittance is 50% is in a range of 600 nm to 650 nm; and
(iv) an average transmittance in a wavelength range of 725 nm to 1000 nm is 5% to 20%.

7. The light-absorbing compound according to claim 6, wherein a ratio of an amount of the second phosphonic acid to an amount of the first phosphonic acid is 1.8 to 9 on a molar basis.

8. The light-absorbing compound according to claim 6, wherein
a ratio of a sum of the amount of the first phosphonic acid and the amount of the second phosphonic acid to amounts of the copper components is 0.3 to 3 on a molar basis.

9. The light-absorbing compound according to claim 8, wherein
a ratio of the amount of the first phosphonic acid to the amounts of the copper components is 0.05 to 0.8 on a molar basis, and
a ratio of the amount of the second phosphonic acid to the amounts of the copper components is 0.2 to 1.5 on a molar basis.

10-13. (canceled)

14. Alight-absorbing composition comprising:
a first light-absorbing compound comprising a copper component and a first phosphonic acid represented by the following formula (a), where R₁ is an alkyl group or a halogenated alkyl group in which at least one hydrogen atom in an alkyl group is substituted with a halogen atom;
a second light-absorbing compound comprising a copper component and a second phosphonic acid represented by the following formula (b), where R₂ is an aryl group or a modified aryl group in which at least one hydrogen atom in an aryl group is substituted with a halogen atom, a nitro group, or a hydroxy group;
a solvent; and
a ratio of an amount of the second phosphonic acid to an amount of the first phosphonic acid is 1.8 to 9 on a molar basis:

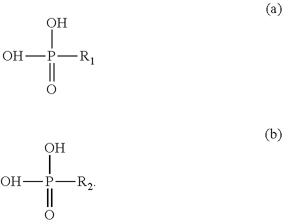

15. The light-absorbing composition according to claim 14, wherein
a ratio of a sum of the amount of the first phosphonic acid and an amount of the second phosphonic acid to amounts of the copper components is 0.3 to 3 on a molar basis.

16. The light-absorbing composition according to claim 14, wherein
a ratio of the amount of the first phosphonic acid to the amounts of the copper components is 0.05 to 0.8 on a molar basis, and
a ratio of the amount of the second phosphonic acid to the amounts of the copper components is 0.2 to 1.5 on a molar basis.

17. The light-absorbing composition according to claim 14, wherein
the light-absorbing composition is capable of being cured into a light absorber with a haze less than 0.2%,
the light absorber is capable of transmitting a light with a third transmission spectrum for an incident light with wavelengths ranging from 300 nm to 1200 nm at an incident angle of 0°, and
the third transmission spectrum satisfies the following requirements (I), (II), (III), (IV), and (V):
(I) an average transmittance in a wavelength range of 460 nm to 600 nm is 75% or more;
(II) a shorter cut-off wavelength that lies in a wavelength range of 350 nm to 450 nm and at which a transmittance is 50% is in a range of 390 nm to 450 nm;
(III) a longer cut-off wavelength that lies in a wavelength range of 600 nm to 700 nm and at which a transmittance is 50% is in a range of 600 nm to 680 nm;
(IV) an average transmittance in a wavelength range of 300 nm to 380 nm is 1.2% or less; and
(V) an average transmittance in a wavelength range of 750 nm to 1100 nm is 1.2% or less.

18. An optical filter comprising the light absorber according to claim 1.

19. A photoelectric conversion element comprising:
a body with a light-receiving face; and
the light absorber according to claim 1,
the light absorber provided so that a light transmitted through the light absorber is incident on the light-receiving face.

20. An ambient light sensor comprising the optical filter according to claim 18.

21. An imaging apparatus comprising the light absorber according to claim 1.

22. The light absorber according to claim 1, further comprising a metal component other than the copper component, wherein
a mass ratio of the amount of the copper component to an amount of the metal component other than the copper component is 1×10² to 7×10².

23. The light absorber according to claim 1, wherein
the light absorber is capable of transmitting a light with a first transmission spectrum for an incident light with wavelengths ranging from 300 nm to 1200 nm at an incident angle of 0°,
the first transmission spectrum satisfying the following requirements (I), (II), (III), (IV), and (V):
(I) an average transmittance in a wavelength range of 460 nm to 600 nm is 75% or more;
(II) a shorter cut-off wavelength that lies in a wavelength range of 350 nm to 450 nm and at which a transmittance is 50% is in a range of 390 nm to 450 nm;
(III) a longer cut-off wavelength that lies in a wavelength range of 600 nm to 700 nm and at which a transmittance is 50% is in a range of 600 nm to 680 nm;
(IV) an average transmittance in a wavelength range of 300 nm to 380 nm is 1.2% or less; and
(V) an average transmittance in a wavelength range of 750 nm to 1100 nm is 1.2% or less.

24. The imaging apparatus according to claim 21, comprising, in sequence:
a plurality of lenses;
the light absorber, the light absorber being provided on a surface of at least one of the plurality of lenses; and
an image sensor.
